(19) United States
(12) Patent Application Publication
(10) Pub. No.: US 2026/0013140 A1
(43) Pub. Date: Jan. 8, 2026

(54) MEMORY CELL ARRANGEMENT AND METHOD

(71) Applicant: Ferroelectric Memory GmbH, Dresden (DE)

(72) Inventors: Bart Vermeulen, Dresden (DE); Alireza Kashir, Dresden (DE); Tony Schenk, Dresden (DE)

(21) Appl. No.: 18/764,427

(22) Filed: Jul. 5, 2024

(51) Int. Cl. H10B 53/30

(52) U.S. Cl. CPC H10B 53/30

(57) ABSTRACT

A memory cell, method, and memory cell arrangement are disclosed, wherein the memory cell arrangement includes a plurality of memory cells each including a memory layer stack over a respective three-dimensional structure, wherein the memory layer stack includes: a first electrode; a memory element substantially consisting of hafnium-zirconium-oxide; and a second electrode disposed over the memory element, wherein the first electrode, the second electrode, and the memory element form a memory capacitor; wherein the first electrode includes a first electrically conductive electrode layer and a first functional ALD layer which is disposed in direct contact with the memory element and substantially consists of an electrically conductive first metal-oxide or an electrically conductive first metal-oxynitride; and wherein the second electrode includes a second functional ALD layer which is disposed in direct contact with the memory element and substantially consists of an electrically conductive second metal-oxide or an electrically conductive second metal-oxynitride.

### TECHNICAL FIELD

Various aspects relate to a memory cell, a method, and a memory cell arrangement.

### BACKGROUND

In general, various computer memory technologies have been developed in semiconductor industry. A fundamental building block of a computer memory may be referred to as memory cell. The memory cell may be an electronic circuit that is configured to store at an information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A to FIG. 1C each show various aspects of a capacitive memory structure in a schematic view;

FIG. 1D and FIG. 1E each show a memory cell arrangement according to various aspects;

FIG. 2A to FIG. 2I each show at least one spontaneously polarizable capacitor structure conformally covering a three-dimensional structure according to various aspects;

FIG. 3A to FIG. 3C each show an exemplary configuration of a spontaneously polarizable capacitor structure according to various aspects;

FIG. 4 shows a flow diagram of a method of manufacturing a memory cell arrangement according to various aspects; and

FIG. 5 and FIG. 6 each show exemplary configurations during forming a functional layer which substantially consists of a metal oxide or metal-oxynitride according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip.

A capacitive memory structure of a memory cell may include a memory element disposed between two electrode layers (e.g., a bottom electrode layer and a top electrode layer). The two electrode layers may, for example, substantially consist of a metal or a metal nitride. It has been found that, in the case that the memory element substantially consists of a spontaneously-polarizable material, such as hafnium zirconium oxide (HZO), and that the memory element is disposed in direct contact with the two electrode layers (which are, for example, made of titanium nitride), the direct interface between an electrode layer and the memory element may lead to reduced electronic properties of the memory cell. It has been found that adding an additional interlayer between an electrode layer and the memory element improves the electronic properties of the memory cell significantly. In a first experimental investigation, a metal oxide layer has been disposed between the bottom electrode layer and the memory element and/or between the top electrode layer and the memory element. In a second experimental investigation, a metal-oxynitride layer has been disposed between the bottom electrode layer and the memory element and/or between the top electrode layer and the memory element. The bottom electrode layer and the top electrode layer were made of titanium nitride and the memory element was made of hafnium zirconium oxide. In both experimental investigations, the memory cell had an increased retention and the (polarization) switching response and a decreased fatigue. “Retention” (in some aspects also referred to as retention time) may be a time the memory cell remains in a state. Hence, “retention” may represent a stability of the memory state the memory cell is written in. “Fatigue” may represent a change of the electronic properties as a function of a number of writing-reading-cycles. Hence, “fatigue” may represent a degradation of the memory cell and a decreased fatigue may refer to less change of the electronic properties with writing-reading-cycles.

Further it has been found that, in the case the metal oxide is tungsten oxide or the metal oxide is tungsten oxynitride, the retention and the (polarization) switching response increase further and the fatigue decreases further.

However, currently there is no process for depositing tungsten oxide by atomic layer deposition within the thermal budget of the electronic device. But, in some scenarios, e.g., in the case that a layer is to be deposited conformally over a three-dimensional structure having an aspect ratio above a threshold value, it may be required to use ALD.

Various aspects relate to methods which allow to deposit a tungsten oxide and tungsten oxynitride using ALD. Further, the methods allow to form a capacitive memory structure having improved electronic properties (e.g., due to improving the interfaces). According to various aspects, a metal nitride (e.g., tungsten nitride) layer is deposited and the metal nitride layer is then oxidized to form the metal oxide (e.g., tungsten oxide) or metal-oxynitride (e.g., tungsten oxynitride). Various aspects relate to devices (e.g., memory cells and/or memory cells) manufactured using one of the methods. Such a device may have a three-dimensional structure (e.g., a trench) requiring ALD for conformally forming for example tungsten oxide.

Herein, various aspects of a functional (ALD) layer substantially consisting of a metal oxide or metal oxynitride are detailed. For illustration, in various aspects, the metal oxide is exemplarily described as being tungsten oxide and the metal oxynitride is exemplarily described as being tungsten oxynitride. It is understood that this serves for illustration and that the metal oxide may be another metal oxide, such as molybdenum oxide, and/or that the metal oxynitride may be another metal oxynitride, such as molybdenum oxynitride.

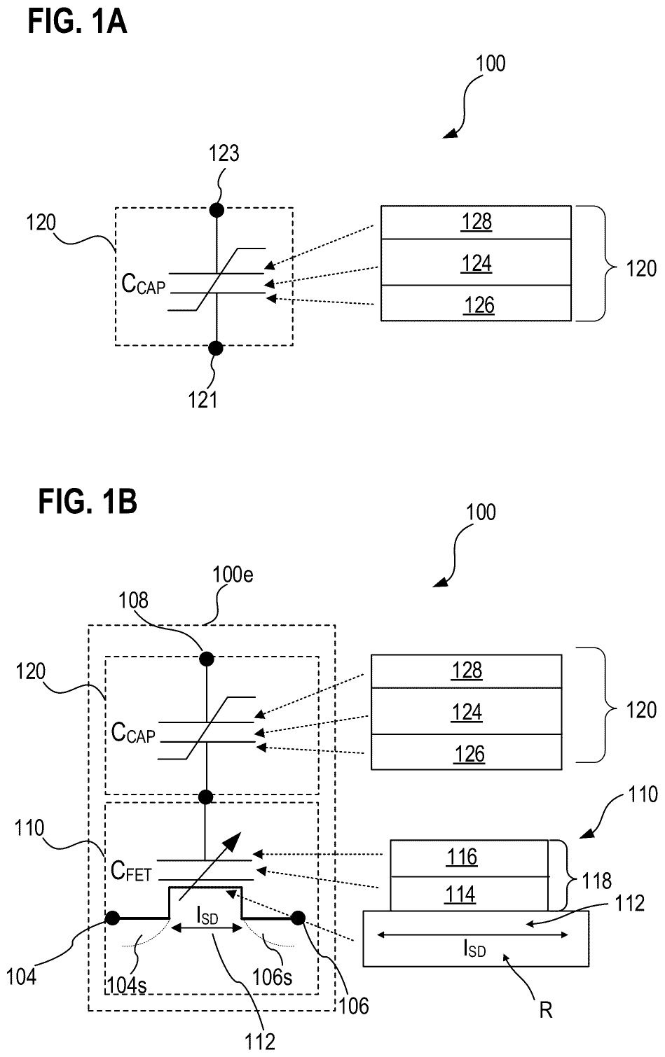

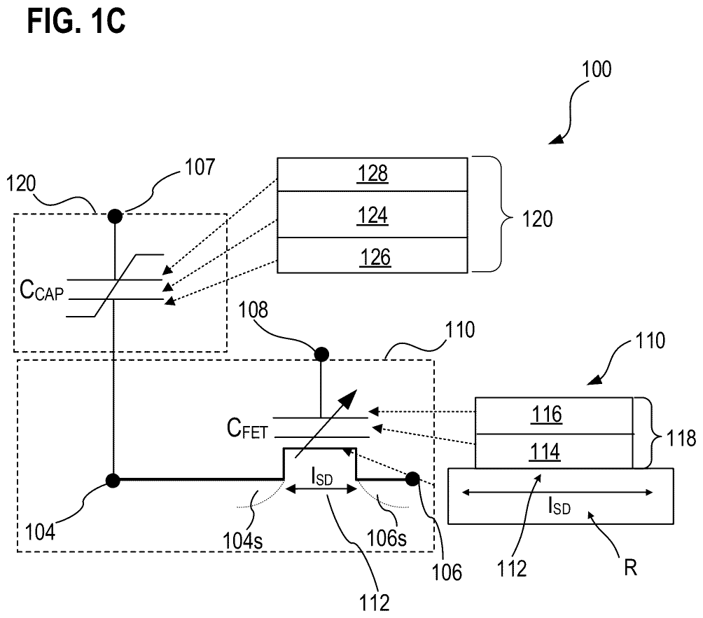

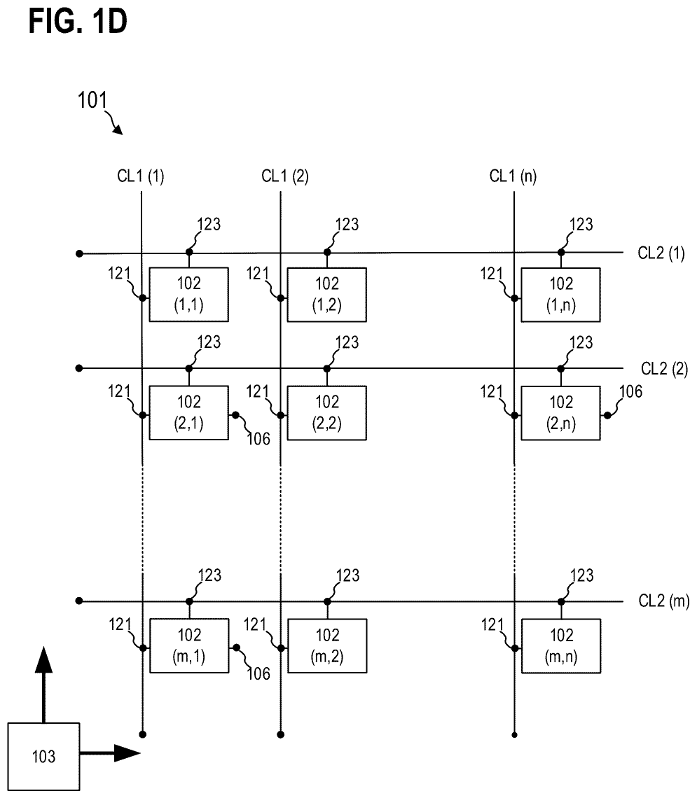

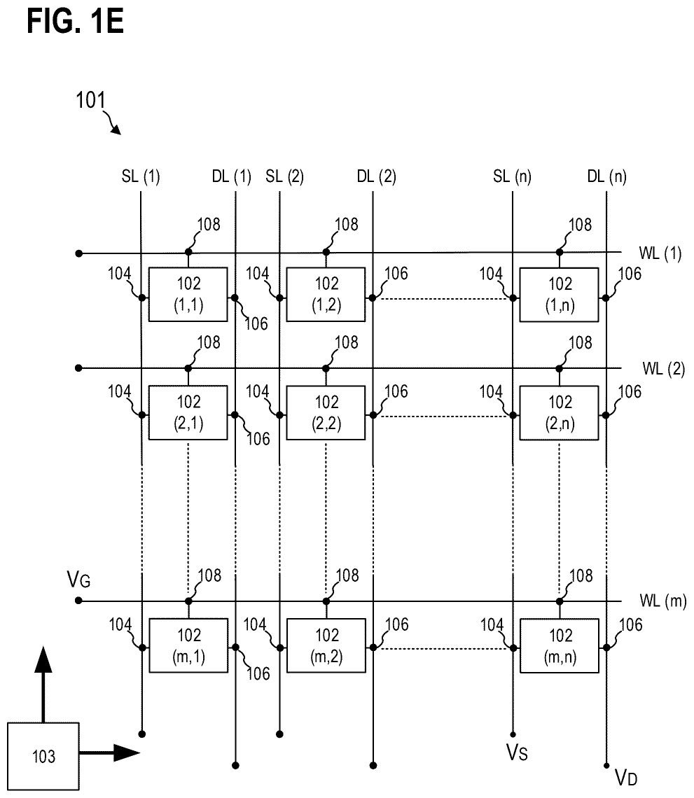

FIG. 1A shows various aspects of a memory structure 100. The memory structure 100 may include a capacitive memory structure, such as a spontaneously polarizable capacitor, SPOC, structure 120. The SPOC structure 120 (in some aspects also referred to as memory layer stack) may include at least two electrodes (e.g., two electrode layers), such as a first electrode 126 and a second electrode 128. The SPOC structure 120 may include a memory element 124. The memory element 124 may be disposed between the first electrode 126 and the second electrode 128. The memory element 124 may be disposed in direct physical contact with the first electrode 126 and in direct physical contact with the second electrode 128. The memory element 124 may include or may consist of a spontaneously polarizable material. A memory element including or consisting of a spontaneously polarizable material may also be referred to as spontaneously-polarizable memory element 124. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 120) spontaneously polarizable properties. According to various aspects, the first electrode 126, the second electrode 128, and the memory element 124 may form the SPOC structure 120. The SPOC structure 120 may, in some aspects, also be referred to as memory capacitor.

The SPOC structure 120 may be part of or may form a memory cell 102. The first electrode 126 may be coupled to a first terminal 121 and the second electrode 128 may be coupled to a second terminal 123. Thus, in this scenario, the memory cell 102 may be a two-terminal memory cell (see, for example, the memory cell arrangement 101 shown in FIG. 1D).

The spontaneously-polarizable memory element 124 may show a hysteresis in the (voltage (drop) dependent) polarization. The spontaneously-polarizable memory element 124 may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element 124. In other aspects, the spontaneously-polarizable memory element 124 may show remanent spontaneous polarization (e.g., may show ferroelectric properties), e.g., the spontaneously-polarizable memory element 124 may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In a usual capacitor structure, the amount of charge stored therein may be used to define a memory state (e.g., first amount of charge stored in the capacitor structure may define a first memory state and a second amount of charge stored in the capacitor structure may define a second memory state.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer.

According to various aspects, the spontaneously-polarizable memory element 124 may include or may consist of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously-polarizable memory element 124 including or being made of a remanent-polarizable material may be referred to herein as remanent-polarizable memory element (e.g., as remanent-polarizable layer).

In some aspects, the spontaneous-polarizable material (e.g., a remanent-polarizable material) may be based on at least one metal oxide. Illustratively, a composition of the spontaneous-polarizable material may include the at least one metal oxide for more than 50%, or more than 66%, or more than 75%, or more than 90%. In some aspects, the spontaneous-polarizable material may include one or more metal oxides. The spontaneous-polarizable material may include (or may be based on) at least one of HfₐO_{b}, ZrₐO_{b}, SiₐO_{b}, YₐO_{b}, LaₐO_{b}, GdₐO_{b}, AlₐO_{b}, as examples, wherein the subscripts “a” and “b” may indicate the number of the respective atom in the spontaneous-polarizable material.

In some aspects, the spontaneous-polarizable material (e.g., the remanent-polarizable material) may be or may include a ferroelectric material, illustratively the memory element 124 may be ferroelectric memory element (for example a ferroelectric layer). A ferroelectric material may be an example of a material used in a spontaneously-polarizable memory element (e.g., in a remanent-polarizable element). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide (also referred to as hafnium zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g., but not limited to it, a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 0.5 cat % (cation percent, such as the metal ion percent) to about 10 cat %, only as an example.

In some aspects, the spontaneous-polarizable material may include hafnium oxide (e.g., may consist of hafnium oxide, hafnium zirconium oxide (e.g., Hf_{0.75}Zr_{0.25}O₂ or Hf_{0.5} Zr_{0.5} O₂), hafnium silicon oxide, hafnium lanthanum oxide, or hafnium lanthanum zirconium oxide), zirconium oxide, and/or aluminum nitride (e.g., may consist of aluminum nitride, aluminum scandium nitride or aluminum boron nitride). In some aspects, the spontaneous-polarizable material may include or may consist of Hf₁₋ₓZrₓO₂, Hf₁₋ₓSiₓO₂, Hf₁₋ₓLaₓO₂, Hf_{1-x-y}LaₓZr_{y}O₂, Al₁₋ₓScₓN, or Al₁₋ₓBₓN.

The spontaneously polarizable material of the memory element 124 may include or may consist of lead zirconate titanate (Pb[ZrₓTi₁₋ₓ]O₃, PZT) or strontium bismuth tantalate (Sr₂Bi₂TaO₉, SBT). However, there are several disadvantages for integrating PZT and SBT in complementary metal-oxide-semiconductor (CMOS):
Polycrystalline PZT or SBT films may require a thickness of more than 70 nm in order to ensure that the complete film is ferroelectric. However, the lateral dimension in CMOS integration may not be scalable such that the thick films lead to huge height difference between the SPOC structure 120 and the logic area forming below the interlayer metallization.
PZT and SBT require four elements and cannot be deposited using atomic layer deposition (ALD). Hence, PZT and SBT cannot be used for a 3D-integration of the SPOC structure 120, but merely for planar structures.
PZT and SBT include elements which may contaminate CMOS facilities. PZT even includes lead (Pb) which is considered toxic. This may require a special encapsulation of the whole SPOC structure 120. Further, dedicated tools may be required for depositing the toxic elements.
PZT and SBT have a comparatively small band gap (e.g., 3.0 to 3.5 eV for PZT). Hence, PZT and SBT cannot be used for devices that require low leakage currents through the SPOC structure 120.

As described, the spontaneously polarizable material of the memory element 124 may consist of hafnium zirconium oxide (Hf₁₋ₓZrₓO₂, HZO) with 0≤x≤1 (i.e., consisting of hafnium oxide in the case of x=0 and consisting of zirconium oxide in the case of x=1). There are several advantages of HZO for CMOS integration:
HZO films are ferroelectric or antiferroelectric down to a thickness of 1 nm. Hence, the integration of the SPOC structure 120 in lateral dimension is scalable to a maximum degree.
HZO films can be deposited using ALD. This allows to manufacture SPOC structure 120 having curved structures and allow a 3D-integration of the SPOC structure 120.
HZO films are CMOS compatible and do not include any toxic elements. Hence, an encapsulation of the SPOC structure 120 may be optional and the standard CMOS equipment can be used.
It may be possible to crystallize the HZO into the ferroelectric phase by annealing at temperatures in a range from about 300° C. to about 400° C. This allows an integration of the SPOC structure 120 as part of the interlayer metallization.
HO films have a large band gap (e.g., 5.8 eV for hafnium oxide). Thus, HZO can be used for devices that require a low leakage current.

According to various aspects, the memory capacitor as provided by the SPOC structure 120 may be or may include a ferroelectric capacitor (FeCAP) or an anti-ferroelectric capacitor (AFeCAP). An information may be stored by the memory capacitor via at least two remanent polarization states of the SPOC structure 120. The programming of the SPOC structure 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

It may be understood that, even though various aspects refer to a memory element including or being made of a spontaneously-polarizable material, other memory elements whose state may be altered by an electric field provided across a capacitive memory structure may be used as long as the structure of the material can be changed via application of an electric field, as described herein.

The SPOC structure 120 may have a capacitive configuration with a (first) capacitance, CCAP, associated therewith (see equivalent circuit 100e in FIG. 1A with respect to the capacitive properties). The first electrode 126, the memory element 124, and the second electrode 128 may form a memory capacitor. In some aspects, the memory capacitor may be a planar layer stack; however, other shapes may be suitable as well, e.g., curved shapes, angled shapes, coaxially aligned shapes, as examples. Illustratively, the SPOC structure 120 may include planar electrodes, or, in other aspects, the SPOC structure 120 may be configured as 3D capacitor including, for example, angled or curved electrodes.

With reference to FIG. 1B, the memory structure 100 may be a field-effect transistor (FET) based capacitive memory structure (e.g., including a ferroelectric FET, FeFET). The memory structure 100 may include a field-effect transistor structure 110 and the capacitive memory structure (e.g., the SPOC structure 120). The SPOC structure 120 may be coupled to a gate structure 118 of the FET. The gate structure 118 may include a gate isolation 114 and a gate electrode 116. The gate structure 118 is illustrated exemplarily as a planar gate stack; however, it is understood that the planar configurations shown in FIG. 1A and FIG. 1B are examples, and that other field-effect transistor designs may include a gate structure 118 with a non-planar shape, for example a trench gate transistor design, a vertical field-effect transistor design, or other designs, such as a fin-FET design.

In this scenario, the memory cell 102 may be a three-terminal memory cell. Thus, the memory cell 102 may have a first terminal 104 (e.g., a source terminal), a second terminal 106 (e.g., a drain terminal), and a third terminal 108 (e.g., a gate terminal). The memory cell 102 may include a field-effect transistor structure 110. The field-effect transistor structure 110 may include a first source/drain region 104s (e.g., a source region). The first source/drain region 104s may be connected to the first terminal 104 of the memory cell 102. The field-effect transistor structure 110 may include a second source/drain region 106s (e.g., a drain region). The second source/drain region 106s may be connected to the second terminal 106 of the memory cell 102. The field-effect transistor structure 110 may include the gate structure 108g (e.g., a gate region). The gate structure 108g may be connected to the third terminal 108 of the memory cell 102.

The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110 (the source/drains are provided in or adjacent to the channel but are not shown in FIG. 1B). The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided at the gate electrode 116 to control the current flow, I_{SD}, in the channel region 112, the current flow, I_{SD}, in the channel region 112 being caused by voltages supplied via the source/drain regions.

According to various aspects, the semiconductor portion (illustratively, where the channel region 112 may be formed), may be made of or may include silicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a wafer made of silicon (e.g., p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

As illustrated by the circuit equivalent in FIG. 1B, a (second) capacitance, C_{FET}, may be associated with the field-effect transistor structure 110. Illustratively, the channel region 112, the gate isolation 114, and the gate electrode 116 may have a capacitance, C_{FET}, associated therewith, originating from the more or less conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, C_{FET}, of the field-effect transistor structure 110 may define one or more operating properties of the field-effect transistor structure 110. The configuration of the field-effect transistor structure 110 (e.g., of the gate isolation 114) may be adapted according to a desired behavior or application of the field-effect transistor structure 110 during operation (e.g., according to a desired capacitance).

In general, the capacitance, C, of a planar capacitor structure may be expressed as,

$$C = {ε}_{0} {ε}_{r} + \frac{A}{d} ,$$

with ε₀ being the permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

In some aspects, the gate electrode 116 of the field-effect transistor structure 110 and the first electrode 126 of the SPOC structure 120 that is connected to the field-effect transistor structure 110 may be spatially separated from one another and electrically connected via a conductive connection, e.g., one or more metal lines. In other aspects, the gate electrode 116 of the field-effect transistor structure 110 and the first electrode 126 of the SPOC structure 120 may be in direct physical contact with one another or implemented as a single (shared) electrode. For example, an electrode layer may (as single (shared) electrode) provide both, the gate electrode 116 of the field-effect transistor structure 110 and the first electrode 126 of the SPOC structure 120.

The SPOC structure 120 may allow adapting the capacitances C_{FET}, C_{CAP} of the respective capacitors to allow an efficient programming of the memory cell. The overall gate voltage required for switching the memory cell from one memory state into another memory state (e.g., from high threshold voltage state to low threshold voltage state, as described below), may become smaller in case the voltage distribution across the field-effect transistor structure 110 and the SPOC structure 120 is adapted such that more of the applied gate voltage drops across the memory layer of the SPOC structure 120 (e.g., across the memory element 124) than across the gate isolation of the field-effect transistor structure 110. The overall write voltage (illustratively, applied via nodes to which the field-effect transistor structure 110 and the SPOC structure 120 are connected) may thus be reduced by adapting the capacitive voltage divider. The voltage distribution may be determined by voltage divider calculations for a series connection of the capacitors.

That is, in the case that the capacitance, CHET, of the field-effect transistor structure 110 is adapted (e.g., by providing a suitable gate isolation) a predefined fraction of the voltage applied to the series connection may drop across the SPOC structure 120. Accordingly, the electric field generated across the gate isolation of the field-effect transistor structure 110 underneath the SPOC structure 120 could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell, that is, to an increased amount of possible state reversals until the memory cell may lose or change its memory properties.

By increasing the capacitance C_{FET} of the field-effect transistor structure 110 (e.g., by providing a gate isolation including a relatively thick layer of material with high dielectric constant), the depolarization field, E_{Dep}, of the spontaneously polarizable material of the memory element 124 may be reduced. The depolarization field may be expressed by the following set of equations, wherein the indices “FET” refer to the capacitor provided by the field-effect transistor structure 110 and the indices “CAP” refer to the capacitor provided by the SPOC structure 120, as described herein:

$${V}_{FET} + {V}_{CAP} = 0 ,$$

$$D = {ε}_{0} {ε}_{FET} {E}_{FET} = {ε}_{0} {ε}_{CAP} {E}_{CAP} + P ,$$

$${E}_{CAP} ≡ {E}_{Dep} = - P {( {ε}_{0} {ε}_{CAP} ( \frac{{C}_{FET}}{{C}_{CAP}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 110 is increased, the depolarization field is reduced. This in turn improves the data retention of the memory cell.

According to various aspects, a threshold voltage of a field-effect transistor structure (and in a corresponding manner the threshold voltage of a field-effect transistor-based memory cell) may be defined as a constant current threshold voltage (referred to as V_{th(ci)}). In this case, the constant current threshold voltage, V_{th(ci)}, may be a determined gate source voltage, V_{GS}, at which the drain current (referred to as I_{D}) is equal to a predefined (constant) current. The predefined (constant) current may be a reference current (referred to as I_{D0}) times the ratio of gate width (W) to gate length (L). The magnitude of the reference current, I_{D0}, may be selected to be appropriate for a given technology, e.g., 0.1 μA. In some aspects, the constant current threshold voltage, V_{th(ci)}, may be determined based on the following equation:

$${V}_{th ( ci )} = {V}_{GS} ( at {I}_{D} = {I}_{D 0} \cdot W / L ) .$$

A threshold voltage of a field-effect transistor structure (e.g., of the field-effect transistor structure 110) may be defined by the properties of the field-effect transistor structure (e.g., the materials, the doping, etc.), and it may thus be a (e.g., intrinsic) property of the field-effect transistor structure.

A memory cell including a field-effect transistor structure may include a first memory state, for example associated with a low threshold voltage state (referred to as LVT associated with the LVT memory state), and a second memory state, for example associated with a high threshold voltage state (referred to as HVT state associated with the HVT memory state). The high threshold voltage state may be, in some aspects, associated with a lower current flow during readout than the low threshold voltage state. The low threshold voltage state may be an electrically conducting state (e.g., associated with a logic memory state “1”, also referred to as a memory state or programmed state) and the high threshold voltage state may be an electrically non conducting state or at least less conducting than the low threshold voltage state (e.g., associated with a logic memory state “0”, also referred to as a memory state or erased state). However, the definition of the LVT state and the HVT state and/or the definition of a logic “0” and a logic “1” and/or the definition of “programmed state” and “erased state” may be selected arbitrarily. Illustratively, the first memory state may be associated with a first threshold voltage of the FET based memory cell, and the second memory state may be associated with a second threshold voltage of the FET based memory cell. However, the definition of the memory states and/or the definition of a logic “0” and a logic “1” may be selected arbitrarily.

According to various aspects, the residual polarization of the memory element 124 (e.g., the polarization of the spontaneously-polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the SPOC structure 120. The amount of charge stored in the SPOC structure 120 may be used to define a memory state of the memory cell. The threshold voltage of a field-effect transistor structure may be a function of the polarization state of the memory element 124, e.g., may be a function of the amount and/or polarity of charge stored in the SPOC structure 120. A first threshold voltage, e.g., a low threshold voltage V_{L-th}, may be associated with the first polarization state (e.g., with the first amount and/or polarity of stored charge), and a second threshold voltage, e.g., a high threshold voltage V_{H-th}, may be associated with the second polarization state (e.g., with the second amount and/or polarity of stored charge). A current flow from nodes to which the field-effect transistor structure and the SPOC structure 120 are coupled may be used to determine the memory state in which the memory cell is residing in.

According to various aspects, writing a memory cell or performing a write operation of a memory cell may include an operation or a process that modifies the memory state the memory cell is residing in from a (e.g., first) memory state to another (e.g., second) memory state. According to various aspects, writing a memory cell may include programming a memory cell (e.g., performing a programming operation of a memory cell), wherein the memory state the memory cell is residing in after programming may be called “programmed state”. For example, programming an n-type FET based memory cell may modify the state the memory cell is residing in from the HVT state to the LVT state, whereas programming a p-type FET based memory cell may modify the state the memory cell is residing in from the LVT state to the HVT state. According to various aspects, writing a memory cell may include erasing a memory cell (e.g., performing an erasing operation of a memory cell), wherein the memory state the memory cell is residing in after the erasing may be called “erased state”. For example, erasing an n-type FET based memory cell may modify the state the memory cell is residing in from the LVT state to the HVT state, whereas erasing a p-type FET based memory cell may modify the state the memory cell is residing in from the HVT state to the LVT state.

Another example of a memory cell having at least two distinct states is a phase-change memory cell. The phase-change memory cell may include a phase change portion. The phase-change portion may be used to implement memory functions, e.g., in a memory cell. The phase-change portion may include a first phase state and a second phase state. For example, a phase-change memory cell may change from a first phase state to a second phase state or vice versa upon applying an electrical signal and may remain in the respective phase state for at least some time (referred to as retention time).

With reference to FIG. 1C, the memory structure 100 may be configured as a 1C1T (one capacitor, one transistor) memory cell. In this case the memory structure 100 may also be referred to as 1C1T ferroelectric capacitive memory (FCM) and/or as (e.g., non-volatile) FERAM. In this case, the first electrode 126 of the SPOC structure 120 may be coupled to the first terminal 104 (as exemplarily shown in FIG. 1C) or to the second terminal 106. An access device, such as the field-effect transistor structure 110 (may also be referred to as access transistor), may allow to control an electrical behavior (e.g., a resistance R) of the channel region 112, thereby allowing to write the memory cell (by storing a charge in the capacitor of the SPOC structure 120) and/or read the memory cell (by detecting a voltage and/or current representing the charge stored in the capacitor of the SPOC structure 120). In this case, the second electrode 128 of the SPOC structure 120 may be connected to or may form a SPOC structure terminal 107.

According to various aspects, a memory device may include a memory cell and a controller (e.g., a memory controller) configured to operate (e.g., read and write) the memory cell. According to various aspects, a memory cell arrangement may include a memory cell and a controller (e.g., a memory controller) configured to operate (e.g., read and write) the memory cell. It is noted that some aspects are described herein with reference to a memory cell of a memory device and/or with reference to a memory cell of memory cell arrangement; it is understood that a memory device and/or a memory cell arrangement may include a plurality of such described memory cells according to various aspects that can be operated in the same way by the controller, e.g., at the same time or in a time sequence. A memory cell arrangement may further include respective sets of control lines and voltage supply levels configured to operate the one or more memory cells of the memory device and/or the memory cell arrangement.

It is noted that a memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well.

In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The memory cell described herein (e.g., as part of a memory cell arrangement) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously-polarizable materials may allow for an integration of the spontaneously polarizable layer via known integration schemes.

According to various aspects, a controller may be configured to provide one or more sets of voltage levels to operate a memory cell arrangement (e.g., including a plurality of memory cells). According to various aspects, a writing operation may be provided based on only two voltage levels (e.g., a first supply voltage level VPP and a second supply voltage level VNN). In the case that the CMOS technology provides electrical access to the bulk, all bulks may be connected to VNN or a voltage significantly similar to VNN but such that no diode from bulk to any source/drain region is forward biased.

FIG. 1D schematically shows an exemplary memory cell arrangement 101 including two-terminal memory cells according to various aspects. Each two-terminal memory cell 102 may be configured as described with reference to FIG. 1A or FIG. 1C. In the case that memory cells 102 are configured in accordance with FIG. 1C, the SPOC structure terminal 107 may be coupled to the base voltage (e.g., ground). The memory cell arrangement 101A may include an array of N times M memory cells. “N” may be any integer number equal to or greater than one. “M” may be any integer number equal to or greater than one.

The memory cell arrangement 101A may include a first set of control lines CL1(n=1 to N) and a second set of control lines CL2(m=1 to M) for individually addressing one or more of the memory cells.

The memory cell arrangement 101A may include a control circuit 103 (e.g., including a read-out circuit and/or a write circuit). The control circuit 103 may be configured to apply a first voltage at the first terminal 121 of a memory cell 102 (m, n) via the corresponding control line CL1(n) of the first set of control lines and to apply a second voltage at the second terminal 123 of the memory cell 102 (m, n) via the corresponding control line CL2 (m) of the second set of control lines in order to address the memory cell 102 (m, n).

FIG. 1E schematically shows the exemplary memory cell arrangement 101 including three-terminal memory cells according to various aspects. Each three-terminal memory cell 102 may be configured as described with reference to FIG. 1B or FIG. 1C.

The memory cell arrangement 101B may include a plurality, n, of first control lines, for example, a plurality of sourcelines SL(n). The memory cell arrangement 101B may include a plurality, n, of second control lines, for example, a plurality of drainlines DL(n). The memory cell arrangement 101B may include a plurality, m, of third control lines, for example, a plurality of wordlines WL(m). For each memory cell 102(m, n) of the plurality of memory cells, the first terminal 104 may be connected to a corresponding sourceline SL(n), the second terminal 106 may be connected to a corresponding drainline DL(n), and the third terminal 108 may be connected to a corresponding wordline WL(m).

The control circuit 103 may be configured to apply a first voltage, V_{S}, at the first terminal 104, a second voltage, V_{D} (e.g., a base voltage), at the second terminal 106, and a third voltage, V_{G}, at the third terminal 108 of a memory cell 102(m, n) in order to address the memory cell 102(m, n).

It is understood that these configurations of the memory cell arrangement 101 serve as examples and that the memory cells 102 may be part of any suitable memory cell arrangement including corresponding control lines for addressing the memory cells 102. Further, it is understood that a memory cell arrangement may include further components such as one or more access devices for addressing the memory cells.

Herein, various exemplary configurations of the SPOC structure 120 are provided according to various aspects. For illustration, various of the configurations of the SPOC structure 120 are exemplarily shown for a planar configuration with planar layers. It is noted that other shapes may be suitable as well, such as curved shapes, angled shapes, coaxially aligned shapes, as examples. In this case, any layer described herein may have a non-planar (e.g., curved) structure. According to various aspects, the SPOC structure 120 may conformally cover a three-dimensional structure. Thus, the shape of the SPOC structure 120 may depend on (e.g., may substantially correspond to) the shape of this three-dimensional structure.

The phrase that “a layer conformally covers a structure” or that “a layer is disposed conformally over a structure” may be understood to mean that a thickness, which is measured normal (e.g., perpendicular) to a surface of the structure (e.g., the three-dimensional structure described herein), is substantially constant along the surface.

In various scenarios, it may be desired or even necessary to form one or more layers conformally over or on a three-dimensional structure, such as a trench. Here, ALD may be advantageous over other deposition methods (such as physical vapor deposition methods). In some cases, e.g., when a feature size (e.g., an aspect ratio) of the three-dimensional structure is equal to or greater than a threshold value (e.g., an aspect ratio equal to or greater than ten), ALD may even be required in order to form the one or more layers conformally over the three-dimensional structure (e.g., conformally within the trench).

According to various aspects, the three-dimensional structure may have a feature size (e.g., an aspect ratio) equal to or greater than six (e.g., equal to or greater than ten, e.g., equal to or greater than fifteen, e.g., equal to or greater than twenty, etc.)

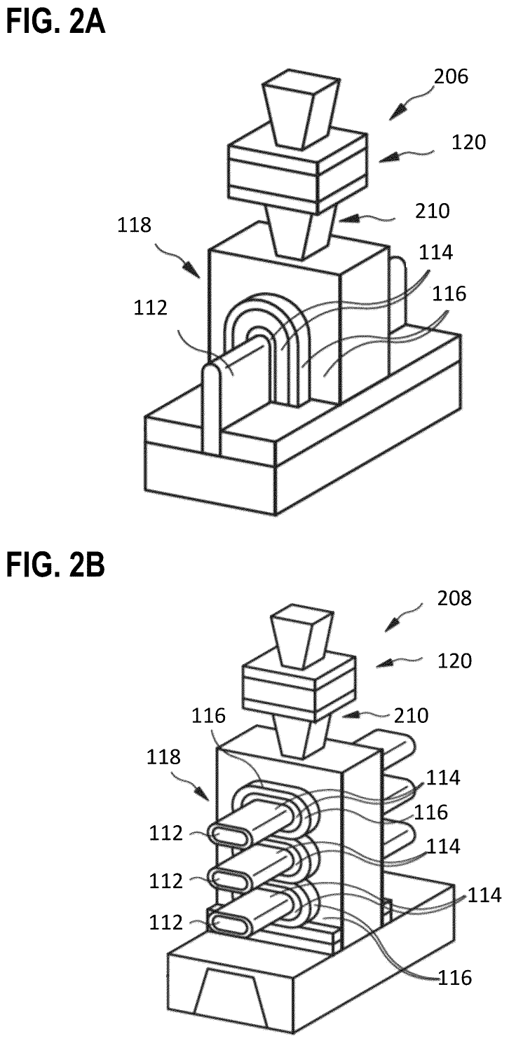

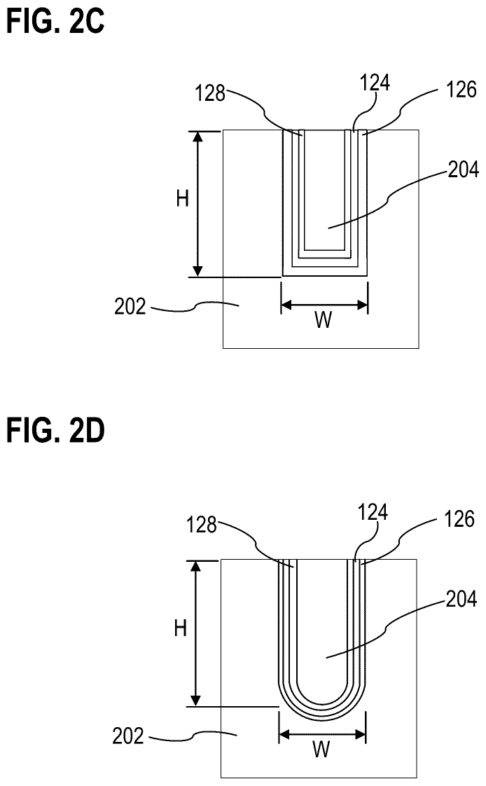

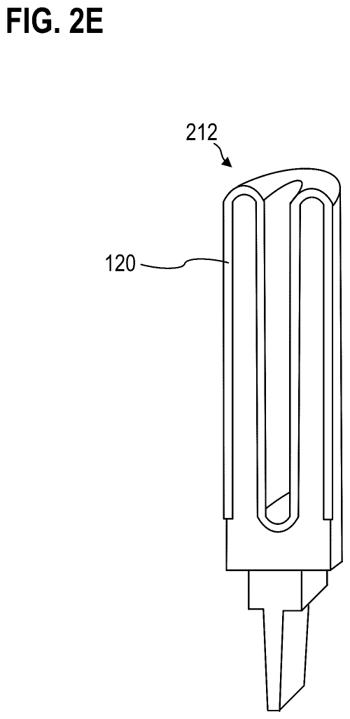

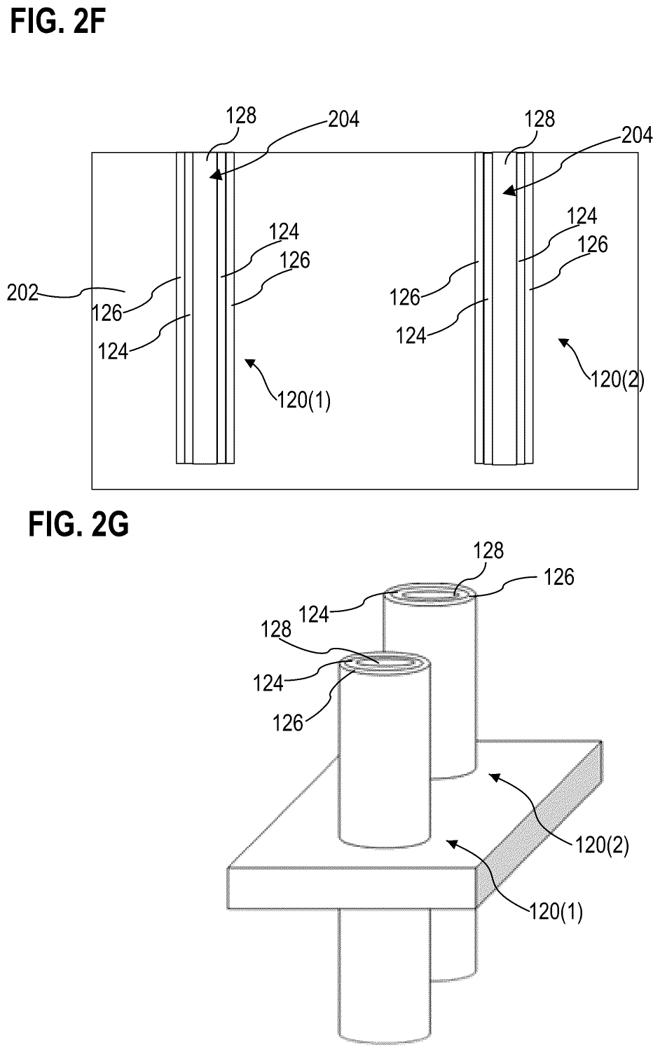

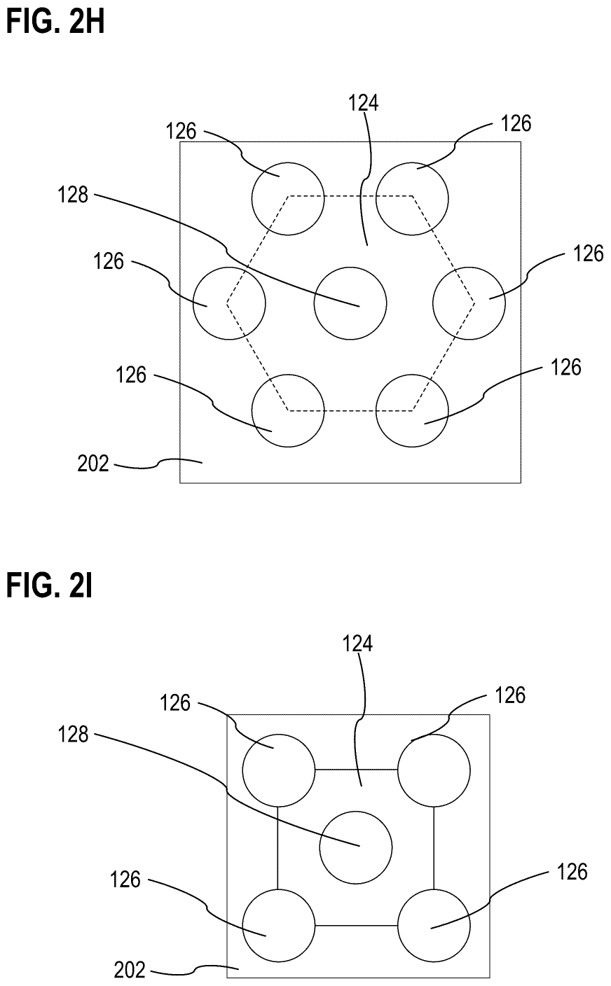

In various cases (e.g., in the exemplary case that the three-dimensional structure is a trench), the feature size may be given by the aspect ratio. The aspect ratio, may be defined by a ratio between the height, H, (which may also be referred to as depth) and the width, W (i.e., a=H/W) of the three-dimensional structure. The width, W, may be measured (e.g., in the case of a curved trench as shown in FIG. 2D) at the surface of the substrate. Thus, in the case of a circular trench, the width, W, may be a diameter of an opening of the circular trench at the surface of the substrate.

However, it is understood that the threshold value at which ALD may be required in order in order to form the one or more layers conformally over the three-dimensional structure may also depend on the width of the three-dimensional structure itself. For example, the width of the three-dimensional structure (e.g., as measured at the surface of the substrate in the case of a trench) may be equal to or less than 200 nm, e.g., equal to or less than 100 nm, e.g., equal to or less than 50 nm (e.g., in combination with the aspect ratio described herein).

It is understood that atomic layer deposition (ALD) generally forms a layer conformally. Thus, in the case that herein a layer is formed over a structure using ALD, the layer is understood to be formed conformally over the structure. Hence, a layer formed over a structure using ALD conformally covers the structure.

FIG. 2A to FIG. 2I each show at least one spontaneously polarizable capacitor structure conformally covering a three-dimensional structure according to various aspects. It is understood that these structures serve for illustration and that the three-dimensional (3D) structure may be another 3D structure (e.g., requiring ALD to form a layer which conformally covers a surface of the 3D structure).

As an example, FIG. 2B shows an integration scheme of a memory cell 102 which may be configured as a fin field-effect transistor (FinFET). The substrate portion in which the channel region 112 is provided may have the shape of a vertical fin, wherein the gate isolation 114 and the gate electrode 116 may at least partially surround the fin. As a further example, FIG. 2C shows a memory cell 102 which may be configured as a nanosheet or nanowire field-effect transistor (also referred to as gate-all-around (GAA) FinFET). The substrate portion(s), in which a respective channel region 112 is provided, may each have the shape of a nanosheet or nanowire. The gate isolation 114 and the gate electrode 116 may at least partially surround the respective nanosheets or nanowires.

Although the SPOC structure 120 of FIG. 2A and FIG. 2B is shown as being substantially planar, it is understood that the SPOC structure may also be non-planar (e.g., conformally disposed within or over the substrate portion 202. These two integration schemes may be configured as detailed with reference to FIG. 1B. For example, the SPOC structure 120 may be integral with the (metal) gate structure 118, e.g., disposed conformally over the (metal) gate structure 118. As an example with reference to the FinFET shown in FIG. 2A, the layers of the SPOC structure 120 may be disposed directly (e.g., conformally) over the gate structure 118. The metal gate structure 118 may, for example, be a replacement metal gate (RMG). As an example with reference to the GAA FinFET shown in FIG. 2B, a portion of the gate dielectric 114 and gate electrode 116 may be disposed around each nanosheet (or nanorods in other aspects) and the layers of the SPOC structure 120 may be disposed conformally around each of these portions.

FIG. 2C and FIG. 2D each show, for illustration, a trench 204 as three-dimensional structure within a substrate portion 202. The SPOC structure 120 may be disposed within the trench 204. The layers of the SPOC structure 120 may be disposed conformally over the substrate portion 202 (i.e., may cover the substrate portion 202 conformally). The trench 204 is shown in FIG. 2C as having a substantially rectangular shape. It is understood that this serves for illustration and that the trench 204 may have another shape. For example, at least a section of an inner wall of the trench 204 may be curved. As an example, a bottom portion of the trench 204 may be curved (see, for example, FIG. 2D). It is understood that the bottom surface and/or top surface of the trench 204 may have any suitable shape, such as one of the following: a circle, a square, a triangle, a parallelogram, a trapezoid, an ellipse, a polygon. The trench 204 may have an aspect ratio equal to or greater than a threshold value (e.g., equal to or greater than six (e.g., equal to or greater than ten, e.g., equal to or greater than fifteen, etc.). As detailed herein, conformally forming the SPOC structure 120 within a trench 204 having an aspect ratio equal to or greater than the threshold value may require atomic layer deposition.

It is understood that the trench 204 serves as an example for illustration and that a “three-dimensional structure”, as described herein, may be any kind of three-dimensional structure such as a nanowire or nanoparticles on a surface of a substrate, or a surface of a porous substrate. A three-dimensional structure may be part of a ferroelectric tunnel junction and/or a selector element. It is understood that these three-dimensional structures are examples for illustration and that the SPOC structure 120 can be formed over other three-dimensional structures by employing the principles describes herein.

As an even further example, FIG. 2E shows a cross-section of an exemplary configuration in which the SPOC structure 120 is disposed on and/or within a cup 212. The cup 212 may be a (hollow) cylindrical structure similar to the ones of a (advanced) dynamic random-access memory (DRAM).

As another example, FIG. 2F shows a cross-section of an exemplary arrangement of two SPOC structures 120(1), 120(2) within a cylindrical trench according to various aspects. FIG. 2G shows a perspective view thereof. As shown, in this scenario the SPOC structure 120 may have a cylindrical shape.

As another example, FIG. 2H shows a top view on an exemplary SPOC structure 120 having a honeycomb-like structure (as indicated by the dashed hexagon). It is understood that the SPOC structure 120 may have a shape in accordance with any other polygon (e.g., having any other number of circular-shaped elements). For example, the SPOC structure 120 may include the circular-shaped elements with a square periodicity as shown in FIG. 2I. Further, according to various aspects, the circular-shaped elements (e.g., of the honeycomb structure and/or the square structure) may be connected to each other via one or more further structures. These further structure may, for example, serve as a support structure and/or as an electrically conductive connection.

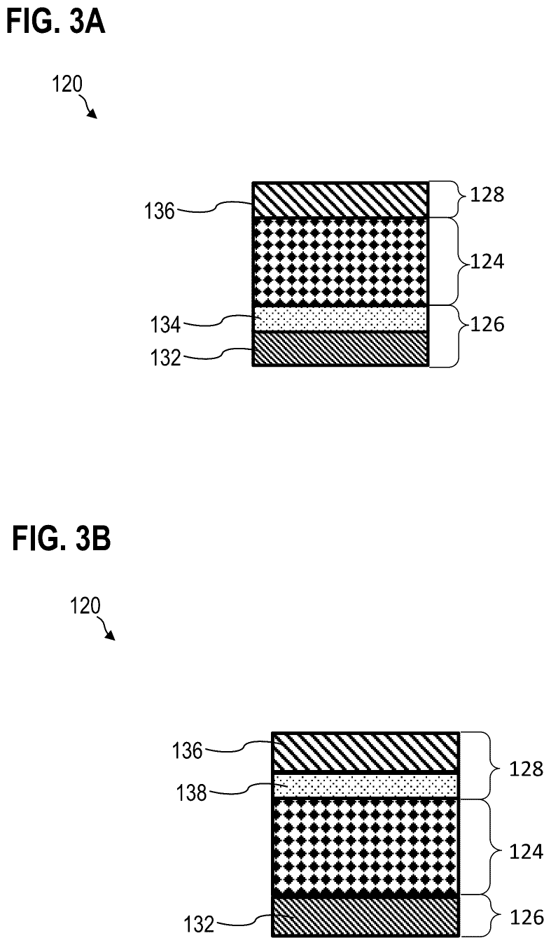

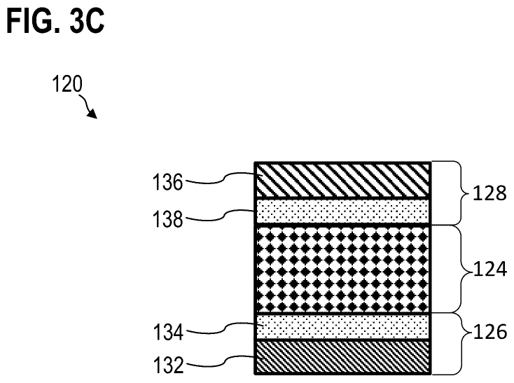

FIG. 3A to FIG. 3C each show an exemplary configuration of the SPOC structure 120 according to various aspects. As described, the SPOC structure 120 may include the memory element 124 (e.g., substantially consisting of the spontaneously polarizable material), the first electrode 126 (which may also be referred to as bottom electrode), and the second electrode 128 (which may also be referred to as top electrode).

The first electrode 126 may include a first electrically conductive electrode layer 132. The second electrode 128 may include a second electrically conductive electrode layer 136. The first electrically conductive electrode layer 132 may substantially consist of a first metal or a first metal nitride. The second electrically conductive electrode layer 136 may substantially consist of a second metal or a second metal nitride. In some aspects, the first electrically conductive electrode layer 132 and the second electrically conductive electrode layer 136 may be made of a same material. In other aspects, the first electrically conductive electrode layer 132 and the second electrically conductive electrode layer 136 may be made of different materials.

The first metal and/or the second metal and/or the metal of the first metal nitride and/or the metal of the second metal nitride may be, for example, a metal of the following list of metals: Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc.

In some aspects, the first metal and/or the second metal may include or may consist of an oxidation resistant metal (e.g., a noble metal). The oxidation resistant metal may have an electronegativity greater than 1.85 on the Pauling scale. The oxidation resistant metal may have a melting temperature greater than 1450° C. This may reduce an oxidation of the interface of the second electrically conductive electrode layer 136. The oxidation resistant metal may include (e.g., consist of), for example, tungsten, platinum, iridium, ruthenium, palladium, osmium, rhodium, molybdenum, cobalt, rhenium, or nickel. According to various aspects, the first electrically conductive electrode layer 132 and/or the second electrically conductive electrode layer 136 may have a work function of the oxidation resistant metal equal to or greater than 5 eV. According to various aspects, using oxidation resistant metal electrode(s) in combination with a spontaneously polarizable material which includes transition-metal-oxides (e.g., as a high-k capacitor dielectric) may suppress a charge injection due to the work function equal to or greater than 5 eV and a comparatively high band-offset. The band-offset may be a conduction band-offset for electrons (between Fermi-level of the electrode and the conduction band of the dielectric layers) or a valance band offset for holes (between Fermi-level of the electrode and the valence band of the dielectric layers).

The first metal nitride and/or the second metal nitride may be, for example, a titanium-based alloy (e.g., TiN, Ti—C—N, Ti—Al—N, TiN—TaN, etc.), a tantalum-based alloy (e.g., TaN, Ta—C—N, TaN—TiN), or a tungsten-based nitride (e.g., WN).

As shown in FIG. 3A and FIG. 3C, the first electrode 126 may include a first functional (ALD) layer 134. The first functional (ALD) layer 134 may be disposed in direct contact with the memory element 124. The first functional (ALD) layer 134 may be disposed in direct contact with the first electrically conductive electrode layer 132. The first functional (ALD) layer 134 may substantially consist of a (e.g., electrically conductive) first metal oxide or a (e.g., electrically conductive) first metal-oxynitride.

As shown in FIG. 3B and FIG. 3C, the second electrode 128 may include a second functional (ALD) layer 138. The second functional (ALD) layer 138 may be disposed in direct contact with the memory element 124. The second functional (ALD) layer 138 may be disposed in direct contact with the second electrically conductive electrode layer 136. The second functional (ALD) layer 138 may substantially consist of a (e.g., electrically conductive) second metal oxide or a (e.g., electrically conductive) second metal-oxynitride.

It has been found that the electronic properties can be improved in the case that the first functional (ALD) layer 134 and the second functional (ALD) layer 138 (if provided) have a thickness greater than 1 nm, optionally in a range from about 1.1 nm to about 9 nm. For example, an experimental investigation revealed that, in the case that the first electrically conductive electrode layer 132 and the second electrically conductive electrode layer 136 are made of titanium nitride and that the memory element is made of HZO, a maximum improvement of the electronic properties is achieved when forming both, the first functional (ALD) layer 134 and the second functional (ALD) layer 138, with a thickness of about 5 nm.

According to various aspects, the electronic properties can be improved when using a symmetric SPOC structure 120. In the case of the symmetric SPOC structure 120, the first electrically conductive electrode layer 132 and the second electrically conductive electrode layer 136 are made of a same material, the first functional (ALD) layer 134 and the second functional (ALD) layer 138 are made of a same material and of a same thickness. The symmetric SPOC structure 120 may suppress the imprint and further improve retention.

Further, it has been found that the electronic properties can be increased when using tungsten as the metal of the metal oxide or metal-oxynitride. Thus, according to various aspects, the first functional (ALD) layer 134 may substantially consist of tungsten oxide or tungsten oxynitride. Accordingly, the second functional (ALD) layer 138 may substantially consist of tungsten oxide or tungsten oxynitride.

As used herein, the first functional (ALD) layer 134 and the second functional (ALD) layer 138 (if provided) may be electrically conductive. Thus, the first metal oxide and/or the second metal oxide and/or the first metal-oxynitride and/or the second metal-oxynitride may be electrically conductive. In the exemplary case of tungsten oxynitride (WO_{3x-y} N₁₋ₓ) it has been found that the electronic properties can be improved in the case that the nitrogen content is equal to or less than 20 at. %

$$( i . e . , \frac{1 - x}{2 x - y + 2} \leq 0.2 )$$

and/or in the case that the oxygen content is equal to or greater than 50 at. %

$$( i . e . , \frac{3 x - y}{2 x - y + 2} \leq \geq 0.5 ) .$$

In the exemplary case of tungsten oxide (WO_{3-y}, with x=1) it has been found that the electronic properties can be improved in the case that the oxygen content is in a range from about 60 at. % to about 74.4 at. % (i.e., 0.1≤y<1.5). Thus, according to various aspects, the oxygen content is less than 75 at. % (i.e., y>0).

As detailed with reference to FIG. 1D and FIG. 1E, a memory cell arrangement (e.g., a ferroelectric random-access memory, FeRAM) may include a plurality of memory cells each including the SPOC structure 120 described herein. The memory cell arrangement may include a substrate providing the substrate portions (202) of the plurality of memory cells. For example, the substrate may be a silicon substrate (e.g., including one or more electronic devices) (e.g., having an oxide layer substantially consisting of a low-k material, such as silicon oxide, disposed thereon). The memory cell arrangement may include a plurality of sets of control lines for selectively addressing one or more memory cells of the plurality of memory cells.

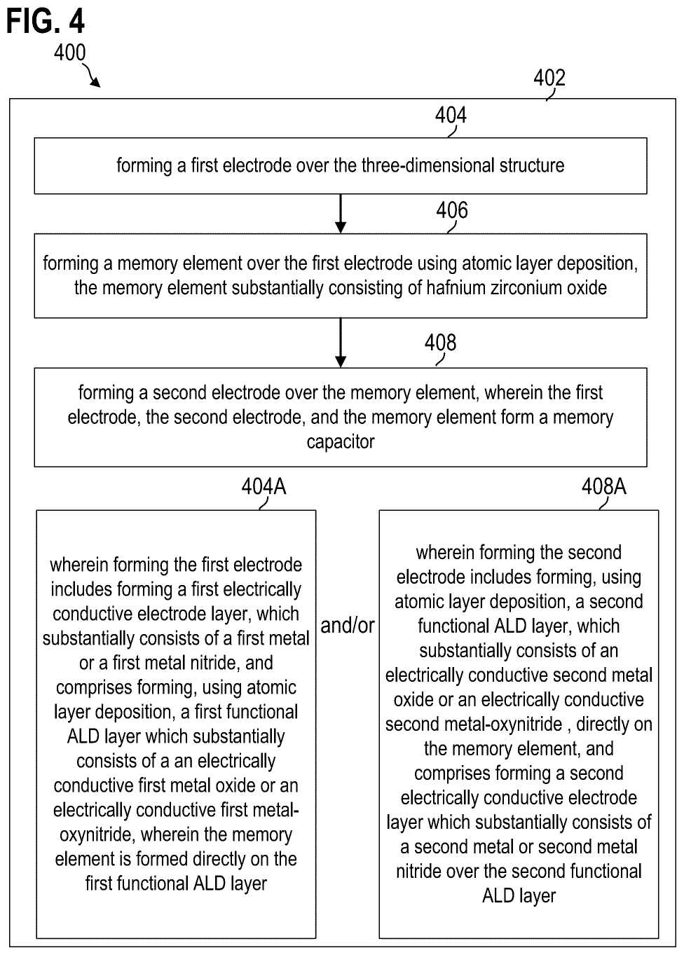

FIG. 4 shows a flow diagram of a method 400 of manufacturing a memory cell according to various aspects. The memory cell may include the SPOC structure 120 described herein.

The method 400 may include (in 402) forming a memory stack over a substrate (e.g., a three-dimensional structure of the substrate).

Forming the memory stack may include (in 404) forming a first electrode (e.g., the first electrode 126) over the substrate (e.g., over the three-dimensional structure of the substrate). As detailed herein, the first electrode 126 may include the first electrically conductive electrode layer 132 and the first functional (ALD) layer 134. Accordingly, forming the first electrode may include forming a first electrically conductive electrode layer (e.g., the first electrically conductive electrode layer 132) substantially consisting of a first metal or first metal nitride (e.g., using atomic layer deposition). Optionally, forming the first electrode may include forming a first functional (ALD) layer (e.g., the first functional (ALD) layer 134) over (e.g., directly on) the first electrically conductive electrode layer using ALD. The first functional (ALD) layer may substantially consist of a first metal oxide (e.g., tungsten oxide) or a first metal-oxynitride (e.g., tungsten oxynitride, WON).

Forming the memory stack may include (in 406) forming a memory element (e.g., the memory element 124) over the first electrode. The memory element may be formed directly on the first functional (ALD) layer. The memory element may substantially consist of a spontaneously-polarizable material. According to various aspects, the spontaneously-polarizable material may be hafnium zirconium oxide (HZO).

Forming the memory stack may include (in 408) forming a second electrode (e.g., the second electrode 128) over the memory element. The first electrode, the memory element, and the second electrode may form a memory capacitor (e.g., the SPOC structure 120). As detailed herein, the second electrode 128 may include the second electrically conductive electrode layer 136 and optionally the second functional (ALD) layer 138. Accordingly, forming the second electrode may include forming a second functional (ALD) layer (e.g., the second functional (ALD) layer 138) substantially consisting of a second metal oxide (e.g., tungsten oxide) or a second metal-oxynitride (e.g., tungsten oxynitride) directly on the memory element using atomic layer deposition and forming a second electrically conductive electrode layer (e.g., the second electrically conductive electrode layer 136) substantially consisting of a second metal over (e.g., directly on) the second functional (ALD) layer (e.g., using atomic layer deposition).

According to various aspects, at least one electrode layer disposed over an oxide layer may be formed using atomic layer deposition (ALD). In some aspects, at least one other layer may be formed using a vapor deposition different from ALD (e.g., a physical vapor deposition (PVD), such as sputtering, or chemical vapor deposition (CDV) different from ALD).

According to various aspects, the first functional (ALD) layer 134 and the second functional (ALD) layer 138 (if provided) may be formed using ALD. As detailed herein, for some metal oxides, such as tungsten oxide, there may be either no ALD process at all or at least no ALD process within the thermal budget of the electronic device (e.g., requiring deposition temperature equal to or greater than 400° C., e.g., greater than 500° C.).

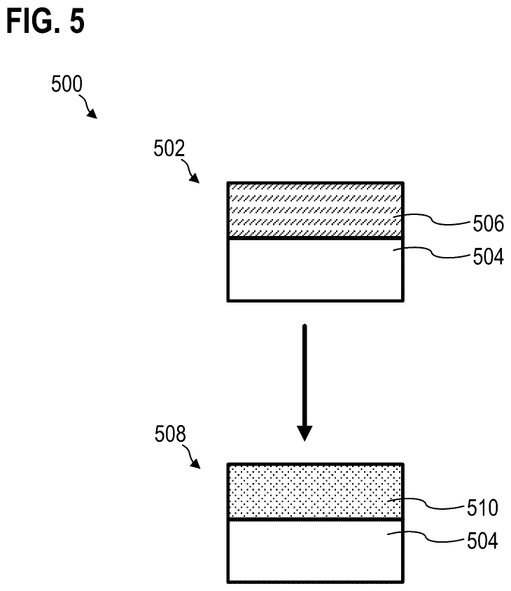

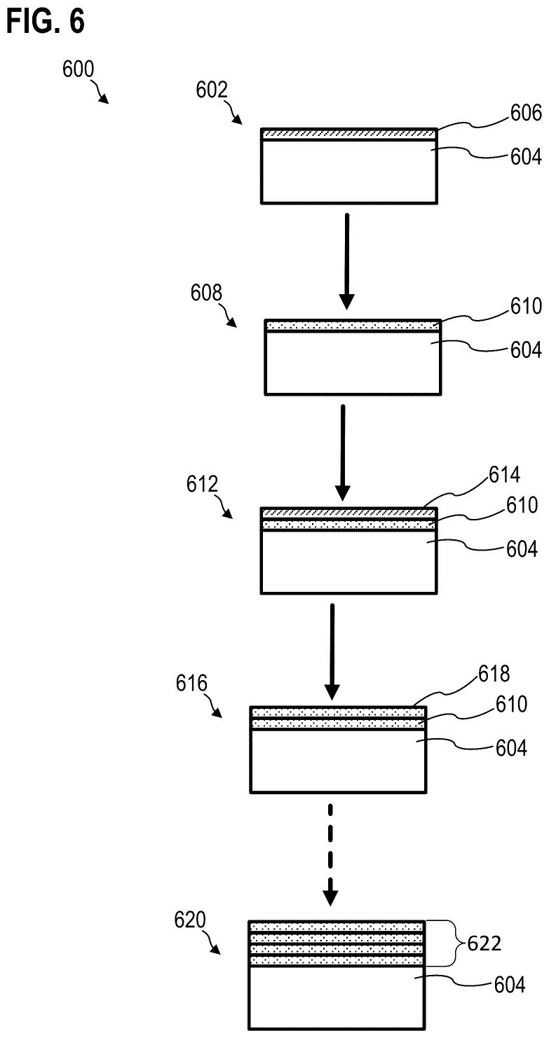

Various aspects refer to a process which allows to form a metal oxide (e.g., tungsten oxide) or metal-oxynitride (e.g., tungsten oxynitride) layer using ALD. This allows to form the metal oxide (e.g., tungsten oxide) or metal-oxynitride (e.g., tungsten oxynitride) conformally over a three-dimensional structure. FIG. 5 and FIG. 6 each show exemplary configurations during forming a functional layer which substantially consists of the metal oxide or metal-oxynitride according to various aspects.

In general, an atomic layer deposition (ALD) of a layer may include various cycles and/or sub-cycles. Each cycle may include one or more precursor pulses and a respective purging after each precursor pulse of the one or more precursor pulses. A precursor pulse may be associated with injecting a gas which includes a respective material of one or more materials to be deposited into a processing chamber in which the memory capacitor is (or is to be) processed. A precursor pulse may be associated with a pulse time defining a time for which the gas is injected into the processing chamber. Each pulse, described herein, may also be associated with a respective process temperature representing a temperature of the substrate and/or the already formed part of the memory capacitor. After each precursor pulse of the one or more precursor pulses, a respective purging may be carried out. Hence, for example, a purging may be carried out between a precursor pulse and a consecutive pulse of an oxidizer (in the case of depositing an oxide layer), or vice versa. A purging may include a purging of remaining gas associated with the respective pulse (e.g., precursor pulse or oxidizer pulse). The purging of the remaining gas may include a purging with another gas, such as nitrogen (N₂). Alternatively, such as in the case of spatial ALD, gas barriers (e.g., a N₂ barrier) may be used instead of purging. Thus, it is understood that between two consecutive pulses described herein (e.g., between a precursor pulse and an oxidizer pulse, or vice versa), a purging may be carried out and/or the substrate may be moved through a gas barrier (e.g., into another chamber).

An atomic layer of a metal layer may be formed by a precursor pulse associated with the metal. According to various aspects, the first electrically conductive electrode layer and/or the second electrically conductive electrode layer may be formed by atomic layer deposition using a metal-organic precursor or a halide precursor. As an example, the first metal and/or the second metal may be tungsten. In this case, the halide precursor may be tungsten fluoride (WF₆). The halide precursor may be used in combination with one or more reducing agents. A reducing agent may be, for example, silane (SiH₄), disilane (Si₂ H₆), or diborane (B₂ H₆). The deposition may be carried out at a temperature in a range from about 200° C. to about 350° C.

In some aspects, an atomic layer of a metal nitride layer may be formed by a precursor pulse associated with the metal of the metal nitride in combination with a nitridation agent. In other aspects, an atomic layer of a metal nitride layer may be formed by a metal-organic precursor (containing the metal of the metal nitride and containing nitrogen) in combination with a reducing agent.

As an example, a metal nitride (e.g., the first metal nitride and/or the second metal nitride) may be titanium nitride.

As a first example, titanium nitride may be deposited by ALD using TiCl₄ as halide precursor in combination with a nitridation agent. The nitridation agent may be NH₃, N₂ H₄, or Dimethylhydrazine. According to some aspects, an additional reducing agent, such as Zn gas, H₂, and/or Trimethylaluminum (TMA) may be used (e.g., which allows to decrease the reaction temperature). For example, using the nitridation agent NH₃ in combination with one of the above additional reducing agents may allow to carry out the ALD process in a temperature range from about 330° C. to about 500° C. The nitridation agent N₂ H₄ may allow to carry out the ALD process in a temperature range from about 300° C. to about 400° C. The nitridation agent Dimethylhydrazine may allow to carry out the ALD process in a temperature range from about 200° C. to about 400° C.

As a second example, titanium nitride may be deposited by ALD using a nitrogen containing metalorganic precursor in combination with a reducing agent, such as Ti(NMe₂)₄ [(CH₃)₂N]₄Ti (TDMAT) as metalorganic precursor in combination with H₂ as reducing agent. This ALD process may allow to carry out the ALD process in a temperature range from about 170° C. to about 250° C.

As a further example, the metal nitride (e.g., the first metal nitride and/or the second metal nitride and/or a sacrificial metal nitride) may be tungsten nitride.

As a first example, tungsten nitride may be deposited by ALD using tungsten fluoride (WF₆) as halide precursor in combination with a nitridation agent. Thus, in general, tungsten nitride may be formed via an ALD deposition of tungsten (e.g., using WF₆ as halide precursor, see above) and a subsequent nitridation (e.g., with ammonia (NH₃)). Hence, in the case that aspects herein refer to a formation of a metal nitride (e.g., tungsten nitride) layer, this formation may include forming a metal layer (e.g., a tungsten layer) by ALD and subsequently nitriding the metal layer to form a metal nitride layer (e.g., a tungsten nitride layer).

As a second example, tungsten nitride may be deposited by ALD using a metalorganic precursor, such as W(NMe₂)₂ (NCMe₃)₂ (e.g., at a temperature of about 400° C.) or (^{t}BuN)₂ (Me₂N)₂ W (e.g., at a temperature in a range from about 250° C. to about 350° C.), in combination a reducing agent, such as ammonia (NH₃). Alternatively, tungsten nitride may be deposited by plasma-enhanced ALD (PE-ALD) using tris(3-hexyne) W(CO) as a metalorganic precursor in an NH₃ plasma. It has been found that, in the case that the tungsten nitride layer is formed on an oxide layer (e.g., the HZO of the memory element 124), tungsten fluoride may at least partially etch a surface of the oxide layer and/or the tungsten layer may not even grow on the oxide. Therefore, according to various aspects, in the case that tungsten nitride is formed as a sacrificial layer (description with reference to FIG. 5 and FIG. 6 below), the tungsten nitride layer may be formed by ALD using the metalorganic precursor.

The memory element 124 may be formed by ALD which may include one or more precursor pulses of a transition metal (e.g., in the case that the memory element is made of HZO). The precursor pulse of the transition metal may include injecting a precursor gas which includes the transition metal into the processing chamber. It is understood that the precursor gas may include other components as well; however, the precursor gas may be configured such that after purging atoms of the transition metal (and optionally further one or more ligands) are deposited at a surface of the processed memory capacitor (the ligands may be reacted (e.g., oxidized) away by a subsequent (e.g., oxygen-containing) precursor pulse). For example, the transition metal may be hafnium and the precursor gas may include hafnium, such as Tetrakis-(ethylmethylamido)-hafnium (TEMA-Hf) or Tetrakis-(dimethylamido)-hafnium (TDMA-Hf). For example, the transition metal may be zirconium and the precursor gas may include zirconium, such as Tetrakis-(ethylmethylamido)-zirconium (TEMA-Zr) or Tetrakis-(dimethylamido)-zirconium (TDMA-Zr). Any chemistry associated with the atomic layer deposition capable to remove ligands of the respective precursor may be used.

An atomic layer of a transition metal oxide memory element may be formed by the respective precursor pulse of one or more transition metals and a pulse of an oxidizer (in some aspects referred to as oxidizer pulse) to oxidize the one or more transition metals. In some aspects, the pulse of an oxidizer may be referred to as precursor pulse of the oxidizer. A pulse of an oxidizer may include injecting a predefined concentration of the oxidizer (e.g. >150 g/Nm³ (gram per Normal cubic meter) into the processing chamber. The oxidizer (in some aspects referred to as oxidizing agent) may include or may be O₃, H₂ O, and/or O₂. For example, a respective pulse time of each pulse of an oxidizer may be in the range from about 1 second to about 30 seconds. Various aspects refer to a pulse of an oxidizer. It is understood that a gas associated with the oxidizer may consist of oxygen atoms, such as O₂, or O₃, or may include other components as well, such as H₂O or H₂O₂.

According to various aspects, a functional (ALD) layer (e.g., the first functional (ALD) layer 134 and/or the second functional (ALD) layer 138) may be electrically conductive (e.g., having an electrical conductivity greater than 106 S/m at a temperature of 20° C.).

As detailed herein, the first functional (ALD) layer 134 may substantially consist of a first metal oxide or a first metal-oxynitride. The second functional (ALD) layer 138 may substantially consist of a second metal oxide or a second metal-oxynitride. Herein, a metal oxide (e.g., the first metal oxide and/or the second metal oxide) and/or a metal-oxynitride (e.g., the first metal-oxynitride and/or the second metal-oxynitride) may be formed by forming a metal nitride layer using ALD and by subsequently oxidizing the metal nitride layer to form the metal oxide or metal-oxynitride. It is understood that depending on an oxidizing time, the metal nitride may either be fully oxidized (thereby forming the metal oxide) or partially oxidized (thereby forming the (e.g., highly oxidized) metal oxynitride). The partial oxidation may at least include an oxidation time such that the resulting metal-oxynitride is electrically conductive.

FIG. 5 shows exemplary configurations during forming (500) a functional ALD layer 510 (e.g., the first functional (ALD) layer 134 and/or the second functional (ALD) layer 138). Forming (500) the functional ALD layer 510 may include forming a metal nitride layer 506 (directly) on an underlying layer 504 (e.g., the first electrically conductive electrode layer 132 in the case of the first functional (ALD) layer 134 and the memory element 124 in the case of the second functional (ALD) layer 138) (see configuration 502). This metal nitride layer 506 (e.g., substantially consisting of tungsten nitride) may then be oxidized (e.g., in a single process) to form the functional ALD layer 510 (see configuration 508). The oxidation may include any suitable oxidizer depending on a material of the metal nitride and the thermal budget of the electronic device. For example, in the case of tungsten nitride, the oxidation may an annealing in an oxidizing environment (e.g., an annealing in an ozone atmosphere or an annealing in air). Annealing in air may allow to oxidize tungsten nitride layers having a thickness greater than 1 μm. Forming (500) the functional ALD layer 510 as described above may result in an oxygen gradient with a decreasing oxygen concentration from a top of the functional ALD layer 510 to a bottom of the functional ALD layer 510. Thus, in the case of the first functional (ALD) layer 134 the oxygen gradient may be associated with an increasing oxygen concentration in direction of the memory element 124. The second functional (ALD) layer 138 may have an oxygen gradient with a decreasing oxygen concentration in direction of the memory element 124.

FIG. 6 shows exemplary configurations during forming (600) a functional ALD layer 622 (e.g., the first functional (ALD) layer 134 and/or the second functional (ALD) layer 138). Forming (600) the functional ALD layer 622 may include forming a plurality of functional ALD sublayers, wherein each functional ALD sublayer of the plurality of functional ALD sublayers may be formed by forming a metal nitride layer and subsequently oxidizing the metal nitride layer (to a metal oxide or metal-oxynitride) prior to forming a next metal nitride layer of the plurality of functional ALD sublayers. For example, forming (600) the functional ALD layer 622 may include forming a first metal nitride sublayer 606 (directly) on an underlying layer 604 (e.g., the first electrically conductive electrode layer 132 in the case of the first functional (ALD) layer 134 and the memory element 124 in the case of the second functional (ALD) layer 138) (see configuration 502). This metal nitride sublayer 606 (e.g., substantially consisting of tungsten nitride) may then be oxidized to form a first functional ALD sublayer 610 (see configuration 608). As detailed herein, an oxidation may include any suitable oxidizer depending on a material of the metal nitride and the thermal budget of the electronic device. The oxidation may be carried out in-situ using an oxidizer pulse (e.g., an ozone pulse) during ALD. The oxidizer pulse may be associated with an annealing (i.e., an increase of the temperature). Subsequently, a second metal nitride sublayer 614 may be formed (directly) on the first metal nitride sublayer 606 (see configuration 612) and may be oxidized to form a second functional ALD sublayer 618 (see configuration 616). This may be iteratively repeated until the plurality of functional ALD sublayers (including two or more ALD sublayers) are formed (which provide the functional ALD layer 622, see configuration 620). When forming the functional ALD layer via the plurality of functional ALD sublayers, the functional ALD layer may have substantially no oxygen gradient. This may improve the electronic properties even further. Each metal nitride sublayer may be oxidized such that the resulting functional ALD sublayer is electrically conductive. For example, in the case of tungsten oxide, the oxidizing may be such that an oxygen content of the functional ALD sublayer is in a range from about 60 at. % to about 74.4 at. % (e.g., in a range from about 60 at. % to about 70 at. %). For example, in the case of tungsten oxynitride, the oxidizing may be such that an oxygen content of the functional ALD sublayer is greater than about 50 at. % and/or that a nitrogen content of the functional ALD sublayer is equal to or less than about 20 at. %.

A metal nitride layer which is converted to a metal oxide or metal oxynitride layer may also be referred to as sacrificial layer, sacrificial metal nitride layer, and/or sacrificial functional layer.

A material of the first electrically conductive electrode layer 132 and/or of the second electrically conductive electrode layer 136 may have an electrical conductivity greater than 106 S/m at a temperature of 20° C. The first electrically conductive electrode layer 132 and/or the second electrically conductive electrode layer 136 may have a thickness less than 10 nm, for example less than 5 nm, for example less than 2 nm. The coefficient of thermal expansion of the first electrically conductive electrode layer 132 and/or the second electrically conductive electrode layer 136 may be below 7 ppm.

A spontaneously polarizable material (e.g., HZO) of the memory element 124 may exhibit the spontaneously polarizable properties only in the crystalline phase. According to some aspects, the spontaneously polarizable material may be deposited already in the crystallized state. According to other aspects, the spontaneously polarizable material may be deposited substantially amorphous and crystallized afterwards. Hence, herein the material of the memory element 124 may be referred to as spontaneously polarizable material even in the amorphous state prior to exhibiting the spontaneously polarizable properties responsive to crystallization.

The spontaneously polarizable material (e.g., HZO) of the memory element 124 may be crystallized by annealing (e.g., thermally annealing). The annealing may include a furnace annealing, a flash-lamp annealing, and/or a laser annealing. The annealing may be carried out in an inert gas atmosphere (e.g., nitrogen, e.g., argon) at any suitable pressure, e.g., at atmospheric pressure, at a pressure below atmospheric pressure, or at a pressure above atmospheric pressure. In some aspects, the annealing may be carried out in a vacuum. A vacuum in a processing chamber (e.g., for depositing a material and/or for annealing a material) may be provided in a pressure range below 50 mbar. For example, it may be possible to crystallize the HZO into the ferroelectric phase by annealing at temperatures in a range from about 300° C. to about 400° C. The crystallized spontaneously polarizable material may be polycrystalline including a plurality of crystallites and the crystallites may have the predefined crystallographic texture, as achieved by means of the amorphous functional layer(s). As an example, a majority of the crystallites (e.g., at least 50%, e.g., at least 75%, e.g., at least 90% of the crystallites) may be oriented along the same direction and therefore define a crystallographic texture. The term “texture”, as used herein, may describe a crystallographic texture as a property of a material or of a layer including a material. The crystallographic texture may be related to a distribution of crystallographic orientations of crystallites of a polycrystalline material. The crystallographic texture may be described by an orientation distribution function (ODF). A crystallographic texture of a layer, as referred to herein, may describe a preferred orientation of the crystallites of a polycrystalline material with reference to a surface of the layer. A crystallographic texture of a layer, as referred to herein, may describe a preferred orientation of the crystallites of a polycrystalline material with reference a direction of an external electric field caused by a voltage applied to electrodes contacting the layer. In other words, a material or layer consisting of crystallites may have no texture in the case that the orientations of the crystallites are randomly distributed. The material or layer may be regarded as a textured material or layer in the case that the orientations of the crystallites show one or more preferred directions. For example, a (001)-texture of the spontaneously polarizable memory layer may describe that most of the crystallites of the polycrystalline material that forms at least part of the spontaneously polarizable memory layer are oriented with their (001)-lattice planes along a direction perpendicular to the (e.g., upper) surface of the spontaneously polarizable memory layer. For example, a (001)-texture of the spontaneously polarizable material of the memory element 124 may describe that most of the crystallites of the polycrystalline material that forms at least part of the spontaneously polarizable material are oriented with their (001)-lattice planes along a direction perpendicular to a growth direction associated with the spontaneously polarizable material. As another example, a (111)-texture of the spontaneously polarizable material of the memory element 124 may describe that most of the crystallites of the polycrystalline material that forms at least part of the spontaneously polarizable material are oriented with their (111)-lattice planes along a direction perpendicular to the (e.g., upper) surface of the spontaneously polarizable material. For example, a (111)-texture of the spontaneously polarizable material may describe that most of the crystallites of the polycrystalline material that forms at least part of the spontaneously polarizable memory layer are oriented with their (111)-lattice planes along a direction perpendicular to a growth direction associated with the spontaneously polarizable memory layer. The (001)-texture may be a (001)-fiber-texture or a (001)-biaxial-texture. The (111)-texture may be a (111)-fiber-texture or a (111)-biaxial-texture. In general, the crystallographic texture may be described by the orientation distribution function (ODF), wherein x-ray diffraction patterns (e.g., pole-figure measurements, e.g., theta-2theta x-ray diffraction measurements with a scattering vector in plane-normal direction, such as perpendicular to a surface of electrodes of a planar capacitive memory structure) or other suitable measurements, e.g., based on transmission electron microscopy, electron backscatter diffraction (EBSD), or transmission Kikuchi diffraction (TKD), may be used to determine the orientation of the crystalline grains of the material.

In some aspects, the substrate may include or may be a silicon substrate e.g., with or without a (e.g., native) SiO₂ surface layer, or any other suitable semiconductor substrate. In other aspects, the substrate may include or may be an electrically non-conductive substrate, e.g., a glass substrate. In still other aspects, the substrate may include or may be an electrically conductive substrate, e.g., a metal substrate.

According to various aspects, a method is provided which allows to form a tungsten oxide (or oxynitride layer) using ALD by first forming a metal nitride layer (e.g., by depositing a metal layer and nitriding the metal layer or by directly depositing the metal nitride layer) and by subsequently oxidizing the metal nitride to form a metal oxide or metal-oxynitride.

In the following, various examples are provided that may include one or more aspects described above with reference to a memory cell including the SPOC structure 120, to a memory cell arrangement including at least one such memory cell, and to the methods described herein. It may be intended that aspects described in relation to one or more of the methods may apply also to the memory cell and/or memory cell arrangement, and vice versa. For example, a method may include at least a part of the formation of the SPOC structure 120.
Example 1 is a memory cell including: a substrate portion; and a memory stack disposed over the substrate portion, the memory stack including: a first electrode disposed over the substrate portion; a memory element disposed over the first electrode, the memory element including a spontaneously polarizable material; and a second electrode disposed over the memory element, wherein the first electrode, the second electrode, and the memory element form a memory capacitor; wherein the first electrode includes a first electrically conductive electrode layer and a first functional (ALD) layer, wherein the first electrically conductive electrode layer substantially consists of a first metal or a first metal nitride, wherein the first functional (ALD) layer substantially consists of a (e.g., electrically conductive) first metal oxide (e.g., tungsten oxide or molybdenum oxide) or a (e.g., electrically conductive) first metal-oxynitride (e.g., tungsten oxynitride or molybdenum oxynitride), wherein the first functional (ALD) layer is disposed in direct contact with the memory element, and/or wherein the second electrode includes a second electrically conductive electrode layer and a second functional (ALD) layer, wherein the second electrically conductive electrode layer substantially consists of a second metal or second metal nitride and wherein the second functional (ALD) layer substantially consists of a (e.g., electrically conductive) second metal oxide (e.g., tungsten oxide or molybdenum oxide) or a (e.g., electrically conductive) second metal-oxynitride (e.g., tungsten oxynitride or molybdenum oxynitride), wherein the second functional (ALD) layer is disposed in direct contact with the memory element.
In Example 2, the subject matter of Example 1 can optionally include that the substrate portion includes a three-dimensional structure.
In Example 3, the subject matter of Example 1 or 2 can optionally include that the first metal oxide and/or the second metal oxide is tungsten oxide or molybdenum oxide; and/or wherein the first metal-oxynitride and/or the second metal-oxynitride is tungsten oxynitride or molybdenum oxynitride.
In Example 4, the subject matter of Example 3 can optionally include that an oxygen content of the tungsten oxide is in a range from about 60 at. % to about 74.4 at. % (e.g., in a range from about 60 at. % to about 70 at. %); and/or wherein an oxygen content of the tungsten oxynitride is equal to or greater than about 50 at. %.
In Example 3, the subject matter of any one of Examples 1 to 4 can optionally include that a first nitrogen content of the first metal-oxynitride is equal to or less than 20 at. %; and/or that a second nitrogen content of the second metal-oxynitride is equal to or less than 20 at. %.
In Example 6, the subject matter of any one of Examples 1 to 5 can optionally include that the first functional layer has an oxygen gradient with an increasing oxygen concentration in direction of the memory element; and/or wherein the second functional layer has an oxygen gradient with a decreasing oxygen concentration in direction of the memory element.
In Example 7, the subject matter of any one of Examples 1 to 5 can optionally include that the first functional layer and the second functional layer have substantially no oxygen gradient.
In Example 8, the subject matter of any one of Examples 1 to 7 can optionally include that the first functional layer conformally covers the first electrically conductive electrode layer; and/or wherein the second functional layer conformally covers the memory element.
In Example 9, the subject matter of any one of Examples 1 to 8 can optionally include that the three-dimensional structure has a width equal to or less than 200 nm and/or an aspect ratio equal to or greater than six (e.g., equal to or greater than ten, e.g., equal to or greater than fifteen, etc.).
In Example 10, the subject matter of any one of Examples 1 to 9 can optionally include that the three-dimensional structure includes at least one of a trench, a cup (e.g., a hollow cylindrical structure), a nanowire, nanoparticles, or a surface of a porous material.
In Example 11, the subject matter of any one of Examples 1 to 10 can optionally include that the spontaneously polarizable material of the memory element substantially consists of one or more transition metal oxides.
In Example 12, the subject matter of any one of Examples 1 to 11 can optionally include that the spontaneously polarizable material of the memory element is a remanent-polarizable material.
In Example 13, the subject matter of any one of Examples 1 to 12 can optionally include that the spontaneously polarizable material of the memory element is hafnium oxide, zirconium oxide, or hafnium zirconium oxide.
In Example 14, the subject matter of any one of Examples 1 to 13 can optionally include that the first metal and/or the second metal is tungsten.
In Example 15, the subject matter of any one of Examples 1 to 14 can optionally include that the first metal nitride is tungsten nitride or titanium nitride; and/or wherein the second metal nitride is tungsten nitride or titanium nitride.
In Example 16, the subject matter of any one of Examples 1 to 15 can optionally include that a metal of the first electrically conductive electrode layer (e.g., the first metal or the metal of the first metal nitride) is a same metal as a metal of the first functional (ALD) layer (e.g., the metal of the first metal oxide or the first metal-oxynitride); or wherein a metal of the first electrically conductive electrode layer (e.g., the first metal or the metal of the first metal nitride) is different from a metal of the first functional (ALD) layer (e.g., the metal of the first metal oxide or the first metal-oxynitride).
In Example 17, the subject matter of any one of Examples 1 to 16 can optionally include that a metal of the second electrically conductive electrode layer (e.g., the second metal or the metal of the second metal nitride) is a same metal as a metal of the second functional (ALD) layer (e.g., the metal of the second metal oxide or the second metal-oxynitride); or wherein a metal of the second electrically conductive electrode layer (e.g., the second metal or the metal of the second metal nitride) is different from a metal of the second functional (ALD) layer (e.g., the metal of the second metal oxide or the second metal-oxynitride).
In Example 18, the subject matter of any one of Examples 1 to 17 can optionally include that the first metal and the second metal are a same metal; or wherein the first metal and the second metal are different metals.
In Example 19, the subject matter of any one of Examples 1 to 18 can optionally include that the first metal nitride and the second metal nitride are a same metal nitride; or wherein the first metal nitride and the second metal nitride are different metal nitrides.
In Example 20, the subject matter of any one of Examples 1 to 19 can optionally include that the first functional layer and/or the second functional layer has a thickness greater than 1 nm (e.g., of about 5 nm), optionally in a range from about 1.1 nm to about 9 nm.
In Example 21, the subject matter of any one of Examples 1 to 20 can optionally include that the first electrically conductive electrode layer is formed by atomic layer deposition (ALD); and/or wherein the second electrically conductive electrode layer is formed by atomic layer deposition (ALD).
In Example 22, the subject matter of any one of Examples 1 to 21 can optionally include that the first functional layer is formed by atomic layer deposition (ALD); and/or wherein the second functional layer is formed by atomic layer deposition (ALD).
In Example 23, the subject matter of any one of Examples 1 to 22 can optionally include that the first functional layer has a first thickness and wherein the second functional layer has a second thickness which is substantially equal to the first thickness.
In Example 24, the subject matter of any one of Examples 1 to 23 can optionally include that the first functional layer is a first functional layer stack including a first plurality of functional layers, wherein each functional layer of the first plurality of functional layers substantially consists of the (e.g., electrically conductive) first metal oxide or first metal-oxynitride (e.g., tungsten oxynitride); and/or wherein the second functional layer is a second functional layer stack including a second plurality of functional layers, wherein each functional layer of the second plurality of functional layers substantially consists of the (e.g., electrically conductive) second metal oxide or second metal-oxynitride (e.g., tungsten oxynitride).
Example 25 is a (e.g., FeRAM) memory cell arrangement including: a plurality of memory cells, wherein at least one (e.g., each) memory cell of the plurality of memory cells is configured in accordance with the memory cell of any one of Examples 1 to 24; a substrate including the substrate portion(s) of the at least one (e.g., each) memory cell; and a plurality of sets of control lines for selectively addressing one or more memory cells of the plurality of memory cells.
Example 26 is a method including: forming a memory stack over a substrate portion by: forming a first electrode over the substrate portion; forming a memory element over the first electrode using atomic layer deposition, the memory element including a spontaneously polarizable material; and forming a second electrode over the memory element, wherein the first electrode, the second electrode, and the memory element form a memory capacitor; wherein forming the first electrode includes forming a first electrically conductive electrode layer, which substantially consists of a first metal or a first metal nitride, and includes forming, using atomic layer deposition, a first functional ALD layer which substantially consists of a (e.g., electrically conductive) first metal oxide (e.g., tungsten oxide or molybdenum oxide) or a (e.g., electrically conductive) first metal-oxynitride (e.g., tungsten oxynitride or molybdenum oxynitride), wherein the memory element is formed directly on the first functional ALD layer, and/or wherein forming the second electrode includes forming, using atomic layer deposition, a second functional ALD layer, which substantially consists of a (e.g., electrically conductive) second metal oxide (e.g., tungsten oxide or molybdenum oxide) or a (e.g., electrically conductive) second metal-oxynitride (e.g., tungsten oxynitride or molybdenum oxynitride), directly on the memory element, and includes forming a second electrically conductive electrode layer which substantially consists of a second metal or second metal nitride over the second functional ALD layer.
In Example 27, the subject matter of Example 26 can optionally include that forming the first functional ALD layer includes: forming a first metal nitride layer using atomic layer deposition; and oxidizing the first metal nitride layer to thereby form the first functional ALD layer.
In Example 28, the subject matter of Example 26 can optionally include that forming the first functional ALD layer includes forming a first functional ALD layer stack including a first plurality of functional ALD layers, wherein forming a respective functional ALD layer of the first plurality of functional ALD layers includes: forming a first metal nitride layer using atomic layer deposition; and oxidizing the first metal nitride layer to thereby form the respective functional ALD layer prior to forming a next functional ALD layer of the first plurality of functional ALD layers.
In Example 29, the subject matter of Example 27 or 28 can optionally include that forming the first metal nitride layer using atomic layer deposition includes forming the first metal nitride layer by atomic layer deposition using a metal-organic precursor or a halide precursor.
In Example 30, the subject matter of Example 29 can optionally include that the metal organic precursor includes the metal of the metal nitride and optionally nitrogen.
In Example 31, the subject matter of any one of Examples 27 to 30 can optionally include that forming the first metal nitride layer using atomic layer deposition includes forming the first metal nitride layer by atomic layer deposition using the metal-organic precursor or the halide precursor and a reducing and/or nitrogenating agent.
In Example 32, the subject matter of any one of Examples 27 to 31 can optionally include that the first metal nitride layer substantially consists of tungsten nitride.
In Example 33, the subject matter of Example 32 can optionally include that oxidizing the first metal nitride layer includes oxidizing the first metal nitride layer such that an oxygen content of the first functional ALD layer is equal to or greater than about 50 at. % (e.g., in a range from about 60 at. % to about 74.4 at. % (e.g., in a range from about 60 at. % to about 70 at. %)).
In Example 34, the subject matter of any one of Examples 32 or 34 can optionally include that oxidizing the first metal nitride layer includes oxidizing the first metal nitride layer such that a nitrogen content of the first functional ALD layer is equal to or less than 20 at. %.
In Example 35, the subject matter of any one of Examples 26 to 34 can optionally include that forming the second functional ALD layer includes: forming a second metal nitride layer using atomic layer deposition; and oxidizing the second metal nitride layer to thereby form the second functional ALD layer.
In Example 36, the subject matter of any one of Examples 26 to 34 can optionally include that forming the second functional ALD layer includes forming a second functional ALD layer stack including a second plurality of functional ALD layers, wherein forming a respective functional ALD layer of the second plurality of functional ALD layers includes: forming a second metal nitride layer using atomic layer deposition; and oxidizing the second metal nitride layer to thereby form the respective functional ALD layer prior to forming a next functional ALD layer of the second plurality of functional ALD layers.
In Example 37, the subject matter of Example 36 or 37 can optionally include that forming the second metal nitride layer using atomic layer deposition includes forming the second metal nitride layer by atomic layer deposition using a metal-organic precursor or a halide precursor.
In Example 38, the subject matter of Example 37 can optionally include that the metal organic precursor includes the metal of the metal nitride and optionally nitrogen.
In Example 39, the subject matter of any one of Examples 35 to 38 can optionally include that forming the second metal nitride layer using atomic layer deposition includes forming the second metal nitride layer by atomic layer deposition using the metal-organic precursor or the halide precursor and a reducing and/or nitrogenating agent.
In Example 40, the subject matter of any one of Examples 35 to 39 can optionally include that the second metal nitride layer substantially consists of tungsten nitride.
In Example 41, the subject matter of Example 40 can optionally include that oxidizing the second metal nitride layer includes oxidizing the second metal nitride layer such that an oxygen content of the second functional ALD layer is equal to or greater than about 50 at. % (e.g., in a range from about 60 at. % to about 74.4 at. % (e.g., in a range from about 60 at. % to about 70 at. %)).
In Example 42, the subject matter of any one of Examples 40 or 41 can optionally include that oxidizing the second metal nitride layer includes oxidizing the second metal nitride layer such that a nitrogen content of the second functional ALD layer is equal to or less than 20 at. %.
In Example 43, the subject matter of Example 29 or 31 can optionally include that the first metal nitride layer substantially consists of tungsten nitride and the halide precursor includes tungsten fluoride.
In Example 44, the subject matter of Example 37 or 39 can optionally include that the second metal nitride layer substantially consists of tungsten nitride and the halide precursor includes tungsten fluoride.
In Example 45, the subject matter of any one of Examples 26 to 44 can optionally include that the substrate portion includes a three-dimensional structure.
In Example 46, the subject matter of Example 45 can optionally include that the three-dimensional structure has a width equal to or less than 200 nm and/or an aspect ratio equal to or greater than six (e.g., equal to or greater than ten, e.g., equal to or greater than fifteen, etc.).
In Example 47, the subject matter of Example 45 or 46 can optionally include that the three-dimensional structure includes at least one of a trench, a cup (e.g., a hollow cylindrical structure), a nanowire, nanoparticles, or a surface of a porous material.
In Example 48, the subject matter of any one of Examples 26 to 47 can optionally include that the spontaneously polarizable material of the memory element substantially consists of one or more transition metal oxides.
In Example 49, the subject matter of any one of Examples 26 to 48 can optionally include that the spontaneously polarizable material of the memory element is a remanent-polarizable material.
In Example 50, the subject matter of any one of Examples 26 to 49 can optionally include that the spontaneously polarizable material of the memory element is hafnium oxide, zirconium oxide, or hafnium zirconium oxide.
In Example 51, the subject matter of any one of Examples 26 to 50 can optionally include that the first metal and/or the second metal is tungsten.
In Example 52, the subject matter of any one of Examples 26 to 51 can optionally include that the first metal nitride is tungsten nitride or titanium nitride; and/or wherein the second metal nitride is tungsten nitride or titanium nitride.
In Example 53, the subject matter of any one of Examples 26 to 52 can optionally include that a metal of the first electrically conductive electrode layer (e.g., the first metal or the metal of the first metal nitride) is a same metal as a metal of the first functional (ALD) layer (e.g., the metal of the first metal oxide or the first metal-oxynitride); or wherein a metal of the first electrically conductive electrode layer (e.g., the first metal or the metal of the first metal nitride) is different from a metal of the first functional (ALD) layer (e.g., the metal of the first metal oxide or the first metal-oxynitride).
In Example 54, the subject matter of any one of Examples 26 to 53 can optionally include that a metal of the second electrically conductive electrode layer (e.g., the second metal or the metal of the second metal nitride) is a same metal as a metal of the second functional (ALD) layer (e.g., the metal of the second metal oxide or the second metal-oxynitride); or wherein a metal of the second electrically conductive electrode layer (e.g., the second metal or the metal of the second metal nitride) is different from a metal of the second functional (ALD) layer (e.g., the metal of the second metal oxide or the second metal-oxynitride).
In Example 55, the subject matter of any one of Examples 26 to 54 can optionally include that the first metal and the second metal are a same metal; or wherein the first metal and the second metal are different metals.
In Example 56, the subject matter of any one of Examples 26 to 55 can optionally include that the first metal nitride and the second metal nitride are a same metal nitride; or wherein the first metal nitride and the second metal nitride are different metal nitrides.
In Example 57, the subject matter of any one of Examples 26 to 56 can optionally include that the first functional layer and/or the second functional layer has a thickness greater than 1 nm (e.g., of about 5 nm), optionally in a range from about 1.1 nm to about 9 nm.
In Example 58, the subject matter of any one of Examples 26 to 57 can optionally include that the first electrically conductive electrode layer is formed by atomic layer deposition (ALD); and/or wherein the second electrically conductive electrode layer is formed by atomic layer deposition (ALD).
In Example 59, the subject matter of any one of Examples 26 to 58 can optionally include that the first functional layer has a first thickness and wherein the second functional layer has a second thickness which is substantially equal to the first thickness.
Example 60 is a method of forming a (e.g., FeRAM) memory cell arrangement, the method including: simultaneously forming a plurality of memory cells over a respective substrate portion of a substrate in accordance with the method of any one of Examples 26 to 59.
In Example 61, the method of Example 60 can optionally further include: forming a plurality of sets of control lines for selectively addressing one or more memory cells of the plurality of memory cells.
Example 62 is a memory cell arrangement including: a substrate including a plurality of three-dimensional structures; a plurality of memory cells; and a plurality of sets of control lines for selectively addressing one or more memory cells of the plurality of memory cells; wherein each memory cell of the plurality of memory cells includes a memory layer stack over a respective three-dimensional structure of the plurality of three-dimensional structures, the memory layer stack including: a first electrode; a memory element disposed over the first electrode, the memory element substantially consisting of hafnium oxide, zirconium oxide, or hafnium zirconium oxide; and a second electrode disposed over the memory element, wherein the first electrode, the second electrode, and the memory element form a memory capacitor; wherein the first electrode includes a first electrically conductive electrode layer and a first functional ALD layer, wherein the first electrically conductive electrode layer substantially consists of a first metal or a first metal nitride, wherein the first functional ALD layer substantially consists of an electrically conductive first metal oxide (e.g., tungsten oxide or molybdenum oxide) or an electrically conductive first metal-oxynitride (e.g., tungsten oxynitride or molybdenum oxynitride), wherein the first functional ALD layer is disposed in direct contact with the memory element, and/or wherein the second electrode includes a second electrically conductive electrode layer and a second functional ALD layer, wherein the second electrically conductive electrode layer substantially consists of a second metal or second metal nitride and wherein the second functional ALD layer substantially consists of an electrically conductive second metal oxide (e.g., tungsten oxide or molybdenum oxide) or an electrically conductive second metal-oxynitride (e.g., tungsten oxynitride or molybdenum oxynitride), wherein the second functional ALD layer is disposed in direct contact with the memory element.
In Example 63, the subject matter of Example 62 can optionally include that the first metal oxide and/or the second metal oxide is tungsten oxide; and/or wherein the first metal-oxynitride and/or the second metal-oxynitride is tungsten oxynitride.
In Example 64, the subject matter of Example 63 can optionally include that an oxygen content of the tungsten oxide is in a range from about 60 at. % to about 74.4 at. % (e.g., in a range from about 60 at. % to about 70 at. %); and/or wherein an oxygen content of the tungsten oxynitride is equal to or greater than about 50 at. %.
In Example 65, the subject matter of any one of Examples 62 to 64 can optionally include that a first nitrogen content of the first metal-oxynitride is equal to or less than 20 at. %; and/or wherein a second nitrogen content of the second metal-oxynitride is equal to or less than 20 at. %.
In Example 66, the subject matter of any one of Examples 62 to 65 can optionally include that the first functional ALD layer has an oxygen gradient with an increasing oxygen concentration in direction of the memory element; and/or wherein the second functional ALD layer has an oxygen gradient with a decreasing oxygen concentration in direction of the memory element.
In Example 67, the subject matter of any one of Examples 62 to 66 can optionally include that the first functional ALD layer is a first functional ALD layer stack including a first plurality of functional ALD layers, wherein each functional ALD layer of the first plurality of functional ALD layers substantially consists of the electrically conductive first metal oxide or electrically conductive first metal-oxynitride (e.g., tungsten oxynitride); and/or wherein the second functional ALD layer is a second functional ALD layer stack including a second plurality of functional ALD layers, wherein each functional ALD layer of the second plurality of functional ALD layers substantially consists of the electrically conductive second metal oxide or electrically conductive second metal-oxynitride (e.g., tungsten oxynitride).
In Example 68, the subject matter of any one of Examples 62 to 67 can optionally include that the respective three-dimensional structure includes at least one of a trench, a cup, a nanowire, nanoparticles, or a surface of a porous material.
In Example 69, the subject matter of any one of Examples 62 to 68 can optionally include that the first functional ALD layer conformally covers the first electrically conductive electrode layer and/or wherein the second functional ALD layer conformally covers the memory element.
In Example 70, the subject matter of any one of Examples 62 to 69 can optionally include that the respective three-dimensional structure has a width equal to or less than 200 nm and/or an aspect ratio equal to or greater than six (e.g., equal to or greater than ten, e.g., equal to or greater than fifteen, etc.).
In Example 71, the subject matter of any one of Examples 62 to 70 can optionally include that the first functional layer and/or the second functional layer has a thickness greater than 1 nm.
In Example 72, the subject matter of any one of Examples 62 to 71 can optionally include that the first metal oxide and the second metal oxide substantially consist of a same material.
In Example 73, the subject matter of any one of Examples 62 to 72 can optionally include that the first functional ALD layer has a first thickness and wherein the second functional ALD layer has a second thickness which is substantially equal to the first thickness.
In Example 74, the subject matter of any one of Examples 62 to 73 can optionally include that the first functional ALD layer and the second functional ALD layer are formed by atomic layer deposition.
Example 75 is a method including: forming a memory stack over a three-dimensional structure of a substrate by: forming a first electrode over the three-dimensional structure; forming a memory element over the first electrode using atomic layer deposition, the memory element substantially consisting of hafnium oxide, zirconium oxide, or hafnium zirconium oxide; and forming a second electrode over the memory element, wherein the first electrode, the second electrode, and the memory element form a memory capacitor; wherein forming the first electrode includes forming a first electrically conductive electrode layer, which substantially consists of a first metal or a first metal nitride, and includes forming, using atomic layer deposition, a first functional ALD layer which substantially consists of a an electrically conductive first metal oxide (e.g., tungsten oxide) or an electrically conductive first metal-oxynitride (e.g., tungsten oxynitride), wherein the memory element is formed directly on the first functional ALD layer, and/or wherein forming the second electrode includes forming, using atomic layer deposition, a second functional ALD layer, which substantially consists of an electrically conductive second metal oxide (e.g., tungsten oxide) or an electrically conductive second metal-oxynitride (e.g., tungsten oxynitride), directly on the memory element, and includes forming a second electrically conductive electrode layer which substantially consists of a second metal or second metal nitride over the second functional ALD layer.
In Example 76, the subject matter of Example 75 can optionally include that forming at least one functional ALD layer of the first functional ALD layer and/or the second functional ALD layer includes: forming a metal nitride layer using atomic layer deposition; and oxidizing the metal nitride layer to thereby form the at least one functional ALD layer.
In Example 77, the subject matter of Example 75 can optionally include that forming the first functional ALD layer and/or the second functional ALD layer includes: forming a functional ALD layer stack including a plurality of functional ALD layers, wherein forming a respective functional ALD layer of the plurality of functional ALD layers includes: forming a metal nitride layer using atomic layer deposition; and oxidizing the metal nitride layer to thereby form the respective functional ALD layer prior to forming a next functional ALD layer of the plurality of functional ALD layers.
In Example 78, the subject matter of Example 76 or 77 can optionally include that the metal nitride layer substantially consists of tungsten nitride.
In Example 79, the subject matter of Example 78 can optionally include that oxidizing the metal nitride layer includes oxidizing the metal nitride layer such that an oxygen content of the respective functional ALD layer is equal to or greater than about 50 at. % (e.g., in a range from about 60 at. % to about 74.4 at. % (e.g., in a range from about 60 at. % to about 70 at. %)).
In Example 80, the subject matter of any one of Examples 78 or 79 can optionally include that oxidizing the metal nitride layer includes oxidizing the metal nitride layer such that a nitrogen content of the respective functional ALD layer is equal to or less than 20 at. %.
In Example 81, the subject matter of any one of Examples 75 to 80 can optionally include that the respective three-dimensional structure has a width equal to or less than 200 nm and/or an aspect ratio equal to or greater than six (e.g., equal to or greater than ten, e.g., equal to or greater than fifteen, etc.).

Several aspects are described with reference to a structure (e.g., a memory transistor structure, a field-effect transistor based memory structure, such as a ferroelectric field-effect transistor based memory structure, a capacitor-based memory structure (e.g., including one or more capacitors), such as a 1C (one capacitor) memory cell or a 1C1T (one capacitor and one transistor) memory cell (wherein the transistor in a 1C1T memory cell is an access transistor) and it is noted that such a structure may include solely the respective element (e.g., a memory transistor, a field-effect transistor, a ferroelectric field-effect transistor, a capacitive memory); or, in other aspects, a structure may include the respective element and one or more additional elements.

The term “switch” may be used herein to describe a modification of the memory state a memory cell is residing in. For example, in the case that a memory cell is residing in a first memory state (e.g., the LVT state), the memory state the memory cell is residing in may be switched such that, after the switch, the memory cell may reside in a second memory state (e.g., the HVT state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously-polarizable memory element (e.g., of a spontaneously-polarizable layer, such as a remanent-polarizable layer). For example, a polarization of a spontaneously-polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell (e.g., from the LVT state into the HVT state, or vice versa).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., source-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bit-line node of the memory cell or the source/drain node of the field-effect transistor memory structure may provide the bit-line node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, a “sourceline voltage” may be provided to a sourceline, and a “plateline voltage” may be provided to a plateline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage (referred to as V_{BL} or VBL) may be varied depending on the intended operation of the memory cell arrangement. Analogously, a wordline voltage (referred to as V_{WL} or VWL), a plateline voltage (referred to as V_{PL} or VPL), and/or sourceline voltage (referred to as V_{SL} or VSL) may be varied depending on the intended operation of a memory cell arrangement. A voltage provided to a node or terminal may be defined by the respective potential applied to that node or terminal relative to the base voltage (referred to as V_{B}) of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell).

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The phrase “a current between” a first terminal or node and a second terminal or node may be used herein to mean a current from the first terminal or node to the second terminal or node as well as a current from the second terminal or node to the first terminal or node.

The phrase “a current through” a terminal, node, or region may be used herein to mean a current from the terminal or node to another terminal, another node, or another region as well as a current to the terminal, node, or region (e.g., from another terminal, another node, or another region).

A current may be detected using a current sense amplifier that outputs a voltage proportional to the current.

The phrase that a layer “substantially consists of” a material, as used herein, may be understood to mean that the layer may include other materials; however, a concentration of the other materials may be significantly lower than a concentration of the material. That the layer “substantially consists of” the material may be understood to mean that the layer includes at least 80 at. % (e.g., at least 90 at. %, e.g., at least 95 at. %, e.g., about 100 at. %) of the material or more (hence, the concentration of the material may be equal to or greater than 80 at. %). For example, a layer that substantially consists of hafnium oxide may consist of hafnium zirconium oxide, Hf₁₋ₓZrₓO₂, with 0.8≤x≤1. It may be understood that even in the case that a layer substantially consists of a specific material (e.g., zirconium oxide (ZrO₂), one or more other materials may diffuse from a neighboring layer into the layer such that the layer may include a small number of atoms of the one or more other materials.

The phrase “substantially different”, as used herein, may be understood to mean that either the first concentration is substantially more than the second concentration or that the second concentration is substantially more than the first concentration. In the following, for illustrative purposes, the second concentration is described to be substantially more than the first concentration. However, it is understood that the first concentration may be substantially more than the second concentration in an analogous manner. The phrase that a second concentration of a second transition metal may be “substantially more” than a first concentration of a first transition metal (or vice versa) may be understood to mean that the second concentration of the second transition metal is at least 1.5-times the first concentration of the first transition metal. For example, the second concentration of the second transition metal may be at least twice the first concentration of the first transition metal. In an exemplary case that a layer includes hafnium zirconium oxide, Hf₁₋ₓZrₓO₂, the second concentration of the second transition metal, Hf, may be substantially more than the first concentration of the first transition metal, Zr, such that 0<x≤0.4. Hence, a concentration of the (second) oxide of the second transition metal (e.g., of HfO₂) may be equal to or greater than 60 at. % (e.g., equal to or greater than 55 at. %, e.g., equal to or greater than 70 at. %, e.g., equal to or greater than 75 at. %, etc.).

As used herein, a “concentration” of an element (e.g., of a transition metal) may refer to an atomic percentage (in at. %) of the element. Thus, in the case that the concentration of one element is compared to the concentration of another element, the atomic percentage of the one element may be compared to the atomic percentage of the other element. It is understood that a relation between the atomic percentage of the one element and the atomic percentage of the other element may directly refer to an atomic ratio between the one element and the other element. For example, in the case that the concentration (e.g., the atomic percentage) of the one element may be two times the concentration (e.g., the atomic percentage) of the other element, the atomic ratio between the one element and the other element may be 2 to 1 (2:1).

The term “metal” or “metal material” may be used herein to describe a metal (e.g., a pure or substantially pure metal) or a mixture of more than one metal, viz. a metal alloy. A “metal” may be an intermetallic material. Illustratively, the term “metal” may be used herein to describe a material having an electrical conductivity typical of a metal, for example an electrical conductivity greater than 10⁶ S/m at a temperature of 20° C. The term “metal material” may be used herein to describe a material having the Fermi level inside at least one band. Therefore, in some aspects, the term “metal” may refer to a metalloid (also referred to as half-metal or semi-metal).

The terms “electrically conducting” or “electrically conductive” may be used herein interchangeably to describe a material or a layer having an electrical conductivity or an average electrical conductivity greater than 10⁶ S/m at a temperature of 20° C. The term “electrically insulating” may be used herein interchangeably to describe a material or a layer having an electrical conductivity or an average electrical conductivity less than 10⁻¹⁰ S/m at a temperature of 20° C. In some aspects, a difference in electrical conductivity between an electrically conducting material (or layer) and an electrically insulating material (or layer) may have an absolute value of at least 10¹⁰ S/m at a temperature of 20° C., or of at least 10¹⁵ S/m at a temperature of 20° C.

The term “content” may be used herein, in some aspects, in relation to the “content of an element” in a material or in a layer to describe the mass percentage (or fraction) of that element over a total mass of the material (or of the layer). The term “content” may be used herein in relation to the “content of defects” in the structure of a material to describe the mass percentage of the defects over a total mass of the constituents of the structure. The term “content” may be used herein, in some aspects, in relation to the “content of an element” in a material or in a layer to describe the volume percentage of that element over a total volume of the material (or of the layer). The term “content” may be used herein in relation to the “content of defects” in the structure of a material to describe the volume percentage of the defects over a total volume of the structure.

The expression “a material of an element” or “a material of a layer”, for example “a material of a memory element”, or “a material of an electrode layer” may be used herein to describe a main component of that element or layer, e.g., a main material (for example, a main element or a main compound) present in that element or layer. The expression “a material of an element” or “a material of a layer” may describe, in some aspects, the material of that element or layer having a weight percentage greater than 60% over the total weight of the materials that the element or layer includes. The expression “a material of an element” or “a material of a layer” may describe, in some aspects, the material of that element or layer having a volume percentage greater than 60% over the total volume of the materials that the element or layer includes. As an example, a material of an element or layer including aluminum may describe that that element or layer is formed mostly by aluminum, and that other elements (e.g., impurities) may be present in a smaller proportion, e.g., having less weight percentage or less volume percentage compared to aluminum. As another example, a material of an element or layer including titanium nitride may describe that that element or layer is formed mostly by titanium nitride, and that other elements (e.g., impurities) may be present in a smaller proportion, e.g., having less weight percentage or less volume percentage compared to titanium nitride.

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g., a layer, a substrate, a wafer, etc.) or “laterally” next to, may be used herein to mean an extent or a positional relationship along a surface of the carrier. That means, in some aspects, that a surface of a carrier (e.g., a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g., perpendicular to the main processing surface of a carrier).

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g., parallel to the main processing surface) the “thickness” of the layer formed on the surface of the support may be the same as the height of the layer.

According to various aspects, various properties (e.g., physical properties, chemical properties, etc.) of a first component (e.g., elements, layers, structures, portions, etc.) and a second component may be compared to one another. It may be found that two or more components may be—with reference to a specific property-either equal to each other or different from one another. As a measure, a value that represents such a property may be either equal or not. In general, a skilled person may understand from the context of the application whether two values or properties are equal or not, e.g., usually, if values are in the range of a usual tolerance, they may be regarded equal. However, in some aspects or as long as not otherwise mentioned or understood, two values that differ from one another with at least 1% relative difference may be considered different from one another. Accordingly, two values that differ from one another with less than 1% relative difference may be considered equal to each other.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

A composition of a layer, a concentration of one or more materials within the layer, a composition of a layer, and/or a concentration of one or more materials within the spontaneously polarizable memory element, etc. may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the layer, the concentration of the one or more materials within the layer, the composition of the spontaneously polarizable memory element, and/or the concentration of the one or more materials within the spontaneously polarizable memory element may be also apparent from a manufacturing protocol for manufacturing the respective layer. For example, a layer may be manufactured by means of deposition, such as atomic layer deposition (ALD) and the respective composition and/or concentration may be directly apparent from the used deposition protocol (e.g., the used ALD deposition protocol).

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

An “electrically conductive” connection or coupling, as described herein, may include a direct electrical connection or an indirect electrical connection, wherein an indirect connection may include additional structures in the current path that have no influence on the substantial functioning of the described circuit or device.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell arrangement, comprising:
a substrate comprising a plurality of three-dimensional structures;
a plurality of memory cells; and
a plurality of sets of control lines for selectively addressing one or more memory cells of the plurality of memory cells;
wherein each memory cell of the plurality of memory cells comprises a memory layer stack over a respective three-dimensional structure of the plurality of three-dimensional structures, the memory layer stack comprising:
a first electrode;
a memory element disposed over the first electrode, the memory element substantially consisting of hafnium zirconium oxide; and
a second electrode disposed over the memory element, wherein the first electrode, the second electrode, and the memory element form a memory capacitor;
wherein the first electrode comprises a first electrically conductive electrode layer and a first functional ALD layer, wherein the first electrically conductive electrode layer substantially consists of a first metal or a first metal nitride, wherein the first functional ALD layer substantially consists of an electrically conductive first metal oxide or an electrically conductive first metal-oxynitride, wherein the first functional ALD layer is disposed in direct contact with the memory element, and
wherein the second electrode comprises a second electrically conductive electrode layer and a second functional ALD layer, wherein the second electrically conductive electrode layer substantially consists of a second metal or second metal nitride and wherein the second functional ALD layer substantially consists of an electrically conductive second metal oxide or an electrically conductive second metal-oxynitride, wherein the second functional ALD layer is disposed in direct contact with the memory element.

2. The memory cell arrangement according to claim 1,
wherein the first metal oxide and/or the second metal oxide is tungsten oxide or molybdenum oxide; and/or
wherein the first metal-oxynitride and/or the second metal-oxynitride is tungsten oxynitride or molybdenum oxynitride.

3. The memory cell arrangement according to claim 2,
wherein an oxygen content of the tungsten oxide is in a range from about 60 at. % to about 74.4 at. %; and/or
wherein an oxygen content of the tungsten oxynitride is equal to or greater than about 50 at. %.

4. The memory cell arrangement according to claim 1,
wherein a first nitrogen content of the first metal-oxynitride is equal to or less than 20 at. %; and/or
wherein a second nitrogen content of the second metal-oxynitride is equal to or less than 20 at. %.

5. The memory cell arrangement according to claim 1,
wherein the first functional ALD layer has an oxygen gradient with an increasing oxygen concentration in direction of the memory element; and/or
wherein the second functional ALD layer has an oxygen gradient with a decreasing oxygen concentration in direction of the memory element.

6. The memory cell arrangement according to claim 1,
wherein the first functional ALD layer is a first functional ALD layer stack comprising a first plurality of functional ALD layers, wherein each functional ALD layer of the first plurality of functional ALD layers substantially consists of the electrically conductive first metal oxide or electrically conductive first metal-oxynitride; and/or
wherein the second functional ALD layer is a second functional ALD layer stack comprising a second plurality of functional ALD layers, wherein each functional ALD layer of the second plurality of functional ALD layers substantially consists of the electrically conductive second metal oxide or electrically conductive second metal-oxynitride.

7. The memory cell arrangement according to claim 1,
wherein the respective three-dimensional structure comprises at least one of a trench, a cup, a nanowire, nanoparticles, or a surface of a porous material.

8. The memory cell arrangement according to claim 1,
wherein the first functional ALD layer conformally covers the first electrically conductive electrode layer and/or wherein the second functional ALD layer conformally covers the memory element.

9. The memory cell arrangement according to claim 1,
wherein the respective three-dimensional structure has a width equal to or less than 200 nm and an aspect ratio equal to or greater than six.

10. The memory cell arrangement according to claim 1,
wherein the first functional layer and/or the second functional layer has a thickness greater than 1 nm.

11. The memory cell arrangement according to claim 1,
wherein the first metal oxide and the second metal oxide substantially consist of a same material.

12. The memory cell arrangement according to claim 1,
wherein the first functional ALD layer has a first thickness and wherein the second functional ALD layer has a second thickness which is substantially equal to the first thickness.

13. The memory cell arrangement according to claim 1,
wherein the first functional ALD layer and the second functional ALD layer are formed by atomic layer deposition.

14. A method, comprising:
forming a memory stack over a three-dimensional structure of a substrate by:
forming a first electrode over the three-dimensional structure;
forming a memory element over the first electrode using atomic layer deposition, the memory element substantially consisting of hafnium zirconium oxide; and
forming a second electrode over the memory element, wherein the first electrode, the second electrode, and the memory element form a memory capacitor;
wherein forming the first electrode comprises forming a first electrically conductive electrode layer, which substantially consists of a first metal or a first metal nitride, and comprises forming, using atomic layer deposition, a first functional ALD layer which substantially consists of a an electrically conductive first metal oxide or an electrically conductive first metal-oxynitride, wherein the memory element is formed directly on the first functional ALD layer, and
wherein forming the second electrode comprises forming, using atomic layer deposition, a second functional ALD layer, which substantially consists of an electrically conductive second metal oxide or an electrically conductive second metal-oxynitride, directly on the memory element, and comprises forming a second electrically conductive electrode layer which substantially consists of a second metal or second metal nitride over the second functional ALD layer.

15. The method according to claim 14,
wherein forming at least one functional ALD layer of the first functional ALD layer and/or the second functional ALD layer comprises:
forming a metal nitride layer using atomic layer deposition; and
oxidizing the metal nitride layer to thereby form the at least one functional ALD layer.

16. The method according to claim 14,
wherein forming the first functional ALD layer and/or the second functional ALD layer comprises: forming a functional ALD layer stack comprising a plurality of functional ALD layers, wherein forming a respective functional ALD layer of the plurality of functional ALD layers comprises:
forming a metal nitride layer using atomic layer deposition; and
oxidizing the metal nitride layer to thereby form the respective functional ALD layer prior to forming a next functional ALD layer of the plurality of functional ALD layers.

17. The method according to claim 16,
wherein the metal nitride layer substantially consists of tungsten nitride.

18. The method according to claim 17,
wherein oxidizing the metal nitride layer comprises oxidizing the metal nitride layer such that an oxygen content of the respective functional ALD layer is equal to or greater than about 50 at. %.

19. The method according to claim 17,
wherein oxidizing the metal nitride layer comprises oxidizing the metal nitride layer such that a nitrogen content of the respective functional ALD layer is equal to or less than 20 at. %.

20. The method according to claim 14,
wherein the respective three-dimensional structure has a width equal to or less than 200 nm and an aspect ratio equal to or greater than six.
